(19) United States
(12) Patent Application Publication
(10) Pub. No.: US 2026/0171950 A1
(43) Pub. Date: Jun. 18, 2026

(54) MOTOR DRIVE CONTROL DEVICE AND MOTOR DRIVE CONTROL METHOD

(71) Applicant: MINEBEA MITSUMI Inc., Nagano (JP)

(72) Inventor: Hidetoshi HIJIKATA, Kitasaku-gun (JP)

(21) Appl. No.: 19/410,049

(22) Filed: Dec. 5, 2025

(30) Foreign Application Priority Data
Dec. 13, 2024 (JP) 2024-218851

(51) Int. Cl. H02P 27/08; H03K 17/13

(52) U.S. Cl. CPC H02P 27/08; H03K 17/133; H02P 2207/05; H02P 2209/01

(57) ABSTRACT

Provided is a motor drive control device capable of reliably avoiding erroneous detection of a zero-cross used for energization switching regardless of the motor load. Such erroneous detection occurs due to the spikes or ringing appearing in a voltage waveform of an induced voltage or a reference voltage. The motor drive control device includes a control circuit that generates a drive control signal for driving a motor including a coil for at least one phase, a drive circuit, and a phase voltage detection circuit. The control circuit, when detecting an occurrence and a resolution of an inductive kickback generated at a coil of a non-energized phase after switching between energized phases to the coil, masks zero-cross detection over a first predetermined time after detecting the resolution of the inductive kickback.

### CROSS REFERENCE TO RELATED APPLICATIONS

This application claims priority benefit of Japanese Patent Application No. 2024-218851 filed on Dec. 13, 2024. The above-referenced application is hereby incorporated herein by reference in its entirety.

### TECHNICAL FIELD

The present invention relates to a motor drive control device and a motor drive control method.

### BACKGROUND ART

The case of sensorless 120-degree rectangular wave driving of a 3 phase BLDC motor (brushless DC motor) is known such that the winding is energized in the energized phase of the PWM (Pulse Width Modulation) drive phase and the GND (ground) phase, and the energization switching is performed by utilizing the zero-cross detection timing of the differential voltage between the induced voltage appearing in the non-energized phase and the neutral point voltage or the reference voltage of ½ of the power supply voltage.

### CITATION LIST

### Patent Literature

Patent Document 1: JP 10-28395 A

### SUMMARY OF INVENTION

### Technical Problem

When a 3 phase BLDC motor is driven by a sensorless 120-degree rectangular wave, an induced voltage and a reference voltage are input to a measurement circuit composed of a comparator and an A/D converter through a resistance voltage dividing circuit and a delay circuit, each limiting a voltage range, by branching a wiring from a winding and a power supply input, thereby detecting a zero-cross.

In such a circuit configuration, when a motor is driven by energization switching for switching energization patterns sequentially and utilizing a zero-cross detection, spikes and ringing are known to be generated in the voltage waveforms of the induced voltage or the reference voltage accompanying the rectangular wave switching. The spikes and ringing are sometimes erroneously detected as a zero-cross used for energization switching. When the spikes and ringing generated in the induced voltage and the reference voltage are erroneously detected as a zero-cross used for energization switching, the energization switching is performed earlier than the original timing, so that there are adverse effects that the rotation speed of the motor becomes unstable, or the rotation speed of the motor becomes high and thus the power consumption per rotation speed deviates from the optimum state.

In the known system, a mask time starting from the switching of the FET is provided as a zero-cross non-detection time in the zero-cross detection in the measurement circuit in addition to the delay circuit of the measurement path, and the spikes or ringing are prevented from being erroneously detected as the zero-cross used for the energization switching.

Setting the mask time starting from the switching of the FET can prevent erroneous detection as the zero-cross used for the energization switching, even when the spike or ringing caused by the switching of the FET is generated according to the driving condition of the motor.

In spite of such a workaround, when the motor is driven by the energization switching at a high rotation, a high output, and a high load by using a high-voltage multipole motor for Drone, the inductive kickback (flyback pulse) is generated by the energization switching and the duration thereof is prolonged, so that the spikes or ringing caused by the resolution of the inductive kickback are generated in the voltage waveform of the induced voltage or the reference voltage, and the zero-cross used for the energization switching is sometimes erroneously detected.

For example, Patent Document 1 describes that the position detection is performed via a position detection mask time setting unit. This position detection mask time setting unit starts the position detection after the lapse of a position detection mask time (zero-cross non-detection time) as a predetermined time for not detecting the variation of the induced voltage generated in the stator winding immediately after switching the energized stator winding. This technique describes that the position detection is performed by changing the position detection mask time according to any one of the operation current, the applied voltage, and the rotation speed of the motor independently or in combination so that the position detection with high accuracy can be performed from a low rotation speed to a high rotation speed.

However, in the technique of Patent Document 1, the duration of the inductive kickback is assumed and set based on the estimation based on the motor load, so that there is a possibility that the zero-cross generated by the spike appearing in the voltage waveform of the induced voltage or the reference voltage actually generated is deviated, and in this case, the problem of erroneously detecting the zero-cross cannot be solved. Further, in the case of energization switching at high rotation, high output, and high load, erroneous detection of the zero-cross utilized for energization switching cannot be dealt with. Such erroneous detection occurs due to the spike or ringing generated at the time of resolving the inductive kickback.

Consequently, a motor drive control device is desired capable of reliably avoiding erroneous detection of the zero-cross utilized for energization switching, even when the motor is driven at high rotation, high output, and high load. Such erroneous detection occurs due to the spikes or ringing appearing in the voltage waveform of the induced voltage or the reference voltage.

The present invention has been made to solve the above-described problems, and an object of the present invention is to provide a motor drive control device capable of reliably avoiding erroneous detection of the zero-cross utilized for energization switching regardless of the motor load. Such erroneous detection occurs due to the spikes or ringing appearing in the voltage waveform of the induced voltage or the reference voltage.

### Solution to Problem

A motor drive control device according to a representative embodiment of the present invention includes:
a control circuit configured to generate a drive control signal for driving a motor including a coil for at least one phase;
a drive circuit including an inverter circuit including switches connected in series with each other,
the switches being provided corresponding to a coil for each phase of the motor, the drive circuit being
configured to:
turn the switches on and off in response to the drive control signal to energize a coil for a corresponding phase; and
switch between energized phases at a predetermined timing to rotate a rotor of the motor; and
a phase voltage detection circuit configured to detect a phase voltage generated between the inverter circuit and a coil for each phase of the motor, in which
the control circuit includes:
a differential voltage detection circuit configured to output, based on the detected phase voltage in each phase, a differential voltage between an induced voltage generated at a coil of a non-energized phase and a reference voltage as a differential voltage detection signal; and
a PWM signal generation unit configured to generate the drive control signal,
the drive control signal being a rectangular wave signal for:
switching between energized phases to the coil based on zero-cross detection using the differential voltage detection signal, and
turning the switches of the inverter circuit on and off to
switch between energized states of the coil of the energized phase, and
the control circuit is configured to
when detecting an occurrence and a resolution of an inductive kickback generated at the coil of the non-energized phase after switching between the energized phases to the coil,
mask the zero-cross detection over a first predetermined time after detecting the resolution of the inductive kickback, and
mask the zero-cross detection over a second predetermined time at rising and falling timings of the rectangular wave signal.

### Advantageous Effects of Invention

According to one aspect of the present invention, the motor drive control device can reliably avoid erroneous detection of the zero-cross used for energization switching regardless of the motor load. Such erroneous detection occurs due to the spikes or ringing appearing in the voltage waveform of the induced voltage or the reference voltage.

### BRIEF DESCRIPTION OF DRAWINGS

FIG. 1 is a diagram illustrating a configuration of a motor unit 100 including a motor drive control device 10 according to an embodiment.

FIG. 2 is a diagram illustrating a functional block configuration of a control circuit 1 in the motor drive control device 10 according to an embodiment.

FIG. 3 is a diagram illustrating a configuration example of a differential voltage detection circuit 15.

FIG. 4 is a diagram illustrating a timing chart for explaining detection of a zero-cross in 1 rotation of the motor (electric angle of 360 degrees) of the motor drive control device 10 according to an embodiment.

FIG. 5 is a diagram for describing respective timings of a PWM drive mask (composite), a PWM energization off mask, and a kickback resolution mask according to an embodiment.

FIG. 6 is a diagram for describing respective timings of a PWM drive mask (composite), a PWM energization off mask, and a kickback resolution mask according to an embodiment.

FIG. 7 is a diagram for describing the respective timings of a PWM drive mask (composite), a PWM energization off mask, and a kickback resolution mask according to an embodiment.

FIG. 8 is a diagram for describing the respective timings of a PWM drive mask (composite), a PWM energization off mask, and a kickback resolution mask according to an embodiment.

FIG. 9 is a flowchart illustrating an example of a processing flow when mask processing is performed in a PWM mask (integrated) by a second mask time (PWM drive mask) and a mask time during an energization off period of an energized phase (PWM energization off mask).

FIG. 10 is a diagram illustrating the timing of a PWM mask (integrated) including a PWM drive mask and a PWM energization off mask in 1 cycle of the PWM drive.

FIG. 11 is a flowchart illustrating an example of a processing flow when mask processing is performed during a first mask time (kickback resolution mask) in the LO side energization switching.

FIG. 12 is a flowchart illustrating an example of a processing flow when mask processing is performed during a first mask time (kickback resolution mask) in the HI side energization switching.

### DESCRIPTION OF EMBODIMENTS

### 1. Overview of Embodiments

First, an outline of a representative embodiment of the invention disclosed in the present application will be described. In the following description, as an example, reference signs in the drawings corresponding to the components of the invention are illustrated in parentheses.

[1]

A motor drive control device (10) according to a representative embodiment of the present invention includes:
a control circuit (1) configured to generate a drive control signal (Sd) for driving a motor (3) including a coil for at least one phase;
a drive circuit (2)
including an inverter circuit (2a) including switches connected in series with each other,
the switches being provided corresponding to a coil for each phase of the motor, the drive circuit (2) being
configured to:
turn the switches on and off in response to the drive control signal to energize a coil for a corresponding phase; and
switch between energized phases at a predetermined timing to rotate a rotor of the motor; and
a phase voltage detection circuit configured to detect a phase voltage generated between the inverter circuit and a coil for each phase of the motor, in which
the control circuit includes:
a differential voltage detection circuit (15) configured to output, based on the detected phase voltage in each phase, a differential voltage between an induced voltage generated at a coil of a non-energized phase and a reference voltage as a differential voltage detection signal (Vd); and
a PWM signal generation unit (14) configured to generate the drive control signal,
the drive control signal being a rectangular wave signal for
switching between the energized phases to the coil based on zero-cross detection using the differential voltage detection signal, and
turning the switches of the inverter circuit on and off to
switch between energized states of the coil of the energized phase, and
the control circuit is configured to,
when detecting an occurrence and a resolution of an inductive kickback generated at the coil of the non-energized phase after switching between the energized phases to the coil,
mask the zero-cross detection over a first predetermined time after detecting the resolution of the inductive kickback, and
mask the zero-cross detection over a second predetermined time at rising and falling timings of the rectangular wave signal.
   [2]

In the motor drive control device according to the above [1],
the switches of the inverter circuit may include high-side switches (Q1, Q3, Q5) and low-side switches (Q2, Q4, Q6),
the PWM signal generation unit may drive the motor by generating the drive control signal for turning on and off the high-side switches and the low-side switches of the inverter circuit to energize the coil, and
the control circuit may mask the zero-cross detection over the second predetermined time at an on/off timing of the switches for a PWM drive phase of the energized phase among the high-side switches and the low-side switches of the inverter circuit.
   [3]

In the motor drive control device according to the above [1],
the control circuit may execute kickback resolution mask processing for masking the zero-cross detection over the first predetermined time after execution of PWM drive mask processing for masking the zero-cross detection over the second predetermined time is completed.
   [4]

In the motor drive control device according to the above [2],
the switches of the inverter circuit include high-side switches and low-side switches, the PWM signal generation unit may drive the motor by generating the drive control signal for turning on and off the switches of the inverter circuit to energize the coil, and
the control circuit may mask the zero-cross detection over an energization off period, the energization off period being a period with the switches for the PWM drive phase of the energized phase turned off.
   [5]

In the motor drive control device according to the above [1],
the control circuit further may detect an occurrence and a resolution of an inductive kickback generated at the coil of the non-energized phase after switching between the energized phases to the coil, and
the control circuit may switch between zero-cross detection modes based on the differential voltage detection signal according to an energization switching mode by,
when an energized phase at a power supply side is switched to another energized phase by HI side energization switching,
setting a variation detection direction of a differential voltage detection signal
at a time of an inductive kickback occurrence to a direction from positive to negative, and
setting a variation detection direction of a differential voltage detection signal at a time of an inductive kickback resolution to a direction from negative to positive, and
when an energized phase at a GND side is switched to another energized phase by LO side energization switching,
setting a variation detection direction of the differential voltage detection signal at a time of an inductive kickback occurrence to a direction from negative to positive, and
setting a variation detection direction of the differential voltage detection signal at a time of an inductive kickback resolution to a direction from positive to negative.
   [6]

In the motor drive control device according to the above [1],
the control circuit may detect the occurrence of the inductive kickback when a first zero-cross is detected within a time of one cycle of PWM driving after switching between the energized phases to the coil.
   [7]

A motor drive control method according to a representative embodiment of the present invention to be executed in a motor drive control device (10) including:
a control circuit (1) configured to generate a drive control signal (Sd) for driving a motor (3) including a coil for at least one phase;
a drive circuit (2) including an inverter circuit (2a) including switches connected in series with each other,
the switches being provided corresponding to a coil for each phase of the motor, the drive circuit (2) being
configured to:
turn the switches on and off in response to the drive control signal to energize a coil for a corresponding phase; and
switch between energized phases at a predetermined timing to rotate a rotor of the motor; and
a phase voltage detection circuit configured to detect a phase voltage generated between the inverter circuit and a coil for each phase of the motor,
the motor drive control method including:
a first step of outputting, based on the detected phase voltage in each phase, a differential voltage between an induced voltage generated at a coil of a non-energized phase and a reference voltage as a differential voltage detection signal (Vd);
a second step of performing zero-cross detection based on the differential voltage detection signal;
a third step of generating the drive control signal,
the drive control signal being a rectangular wave signal for
switching between the energized phases to the coil based on the zero-cross detection, and
turning the switches of the inverter circuit on and off to
switch between energized states of a coil of the energized phase;
a fourth step of detecting an occurrence and a resolution of an inductive kickback generated at the coil of the non-energized phase after switching between the energized phases to the coil; and
a fifth step of masking
the zero-cross detection over a first predetermined time after detecting the resolution of the inductive kickback, and
masking the zero-cross detection over a second predetermined time upon rising and falling of the rectangular wave signal.

### 2. Specific Examples of Embodiments

Specific examples of embodiments of the present invention will be described below with reference to the drawings. In the following description, components common to the respective embodiments are denoted by the same reference signs, and repeated descriptions thereof are omitted.

### Embodiments

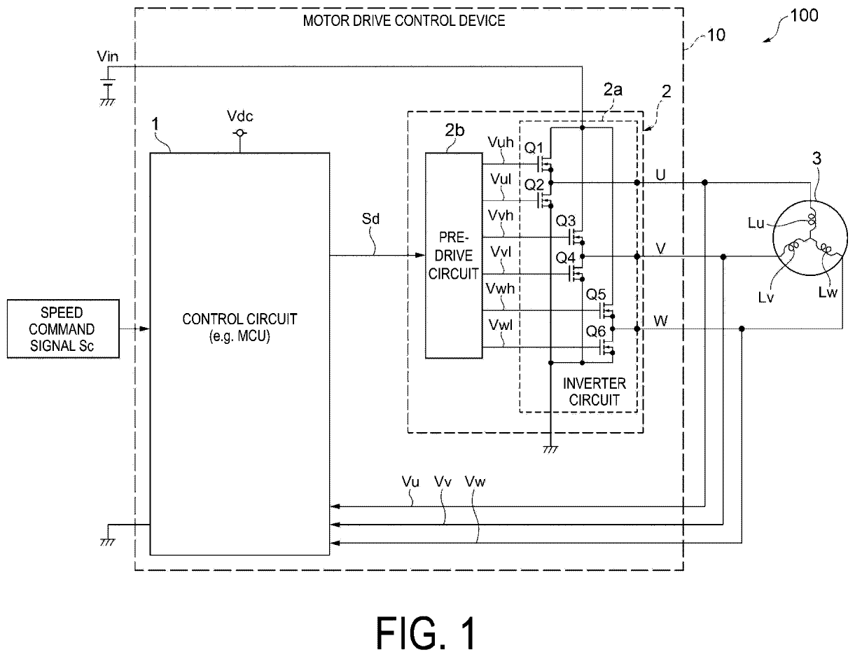

FIG. 1 is a diagram illustrating a configuration of a motor unit 100 including a motor drive control device 10 according to the embodiment.

As illustrated in FIG. 1, the motor unit 100 includes a motor 3 and the motor drive control device 10 for controlling rotation of the motor 3. The motor unit 100 is applicable to various devices that use a motor as a driving source such as fans and drones (unmanned aerial vehicles), for example.

The motor 3 is a permanent magnet synchronous motor (PMSM), for example. In the present embodiment, a motor 3 is, for example, a surface magnet synchronous motor (SPMSM) having three-phase coils (windings) Lu, Lv, and Lw. Coils Lu, Lv and Lw are, for example, Y (star) connected to each other. At this time, the coils may be Δ (delta) connected to each other.

The motor drive control device 10, by applying, for example, a 120-degree energization rectangular wave drive signal to the motor 3, periodically supply a drive current to the 3-phase coils Lu, Lv and Lw of the motor 3 to rotate the rotor of the motor 3.

The motor drive control device 10 includes the control circuit 1 and a drive circuit 2.

Note that the components of the motor drive control device 10 illustrated in FIG. 1 are some of the entire components, and the motor drive control device 10 may include other components in addition to the components illustrated in FIG. 1.

The drive circuit 2 drives the motor 3 based on a drive control signal Sd output from the control circuit 1 described below. The drive circuit 2 includes, for example, an inverter circuit 2a and a pre-drive circuit 2b. The inverter circuit 2a of the drive circuit 2 is disposed between a DC power supply Vin and the ground potential.

The inverter circuit 2a is a circuit for driving the coils Lu, Lv, and Lw of the motor 3 as a load based on the drive control signal Sd output from the control circuit 1 and input via the pre-drive circuit 2b. Specifically, in an embodiment, the inverter circuit 2a includes three switching legs each including two drive transistors connected in series, and drives the motor 3 as a load based on the input drive control signal Sd by alternately turning the two drive transistors on and off (switching operation).

More specifically, the inverter circuit 2a includes switching legs corresponding to the U, V, and W phases of the motor 3, respectively. As illustrated in FIG. 1, each of the switching legs corresponding to respective phases include two drive transistors (hereinafter referred to also as “switching elements”) Q1 and Q2, Q3 and Q4, and Q5 and Q6 connected in series between the DC power supply Vin and the ground potential.

Here, the drive transistors Q1, Q3, and Q5 (corresponding to high-side switches) of the upper arms of the coils of the motor 3 are, for example, N-channel MOSFETs. The drive transistors Q2, Q4, and Q6 (corresponding to low-side switches) of the lower arms of the coils of the motor 3 are, for example, N-channel MOSFETs. The drive transistors Q1 to Q6 may be other types of FETs, for example, other types of transistors such as IGBT (Insulated Gate Bipolar Transistor).

For example, the switching leg corresponding to the U-phase includes the switching elements Q1 and Q2 connected in series with each other. The point commonly connecting the switching element Q1 and the switching element Q2 is connected to one end of the coil Lu as a load. The switching leg corresponding to the V-phase includes the switching elements Q3 and Q4 connected in series with each other. The point commonly connecting the switching element Q3 and the switching element Q4 is connected to one end of the coil Lv as a load. The switching leg corresponding to the W-phase includes the switching elements Q5 and Q6 connected in series with each other. The point commonly connecting the switching element Q5 and the switching element Q6 is connected to one end of the coil Lw as a load. The switching elements Q1 and Q2, Q3 and Q4, Q5 and Q6 each have parasitic diode characteristics in the direction from the GND side to the power supply side (not illustrated in FIG. 1).

The pre-drive circuit 2b generates a drive signal for driving the inverter circuit 2a based on the drive control signal Sd output from the control circuit 1.

The drive control signal Sd is a signal for controlling the drive of the motor 3 and is a rectangular wave signal, for example, a PWM (Pulse Width Modulation) signal. Specifically, the drive control signal Sd is a signal for switching the energization patterns of the coils Lu, Lv, and Lw of the motor 3 determined by the on/off state of each switching element constituting the inverter circuit 2a. More specifically, the drive control signal Sd includes six types of PWM signals corresponding to the respective switching elements Q1 to Q6 of the inverter circuit 2a.

Based on the six types of PWM signals (rectangular wave signals) as the drive control signal Sd supplied from the control circuit 1, the pre-drive circuit 2b generates six types of drive signals Vuh, Vul, Vvh, Vvl, Vwh, and Vwl capable of providing sufficient power to drive the control electrodes (gate electrodes) of the respective switching elements Q1 to Q6 of the inverter circuit 2a.

When these drive signals Vuh, Vul, Vvh, Vvl, Vwh, and Vwl are input to the control electrodes (gate electrodes) of the respective switching elements Q1 to Q6 of the inverter circuit 2a, the switching elements Q1 to Q6 each performs on/off operation (switching operation). For example, each of the switching elements Q1, Q3, and Q5 of the upper arm and a corresponding one of the switching elements Q2, Q4, and Q6 of the lower arm, alternately performs on/off operations, for the switching leg corresponding to each phase. Thus, power is supplied from the DC power supply Vin to each phase of the motor 3, thereby rotating the motor 3.

A wiring (hereinafter also referred to as “phase voltage detection circuit”) for measuring the phase voltage signals Vu, Vv, Vw generated in each phase is connected between the inverter circuit 2a and the coil Lu, Lv, Lw of the corresponding phase of the motor 3, and is input to the control circuit 1. In the control circuit 1, during the zero-cross detection described later, a differential voltage measured based on the phase voltage signals Vu, Vv, and Vw generated in each phase is utilized. The differential voltage is a value corresponding to the selected phase voltage, as the differential voltage between the induced voltage of one phase selected as the non-energized phase and a reference voltage (either the neutral point voltage or ½ of the power supply voltage). That is, a zero-cross can be detected by detecting that the differential voltage signal Vd, as a differential voltage between an induced voltage and a reference voltage, becomes zero.

In the drive of the motor, the control circuit 1 generates the drive control signal Sd for driving the motor 3 based on, for example, a speed command signal Sc, input from the outside and indicating the target operation state of the motor 3, and controls the drive of the motor 3. Specifically, the control circuit 1 generates the drive control signal Sd so that the motor 3 enters the operation state specified by the speed command signal Sc, and then the generated drive control signal Sd is provided to the drive circuit 2. At this time, the control circuit 1 detects a zero-cross to be used for energization switching by using the differential voltages measured based on the phase voltage signals Vu, Vv, and Vw, and generates the drive control signal Sd for switching between the energized phases of the motor 3 at an appropriate timing.

In the embodiment, the control circuit 1 is a program processing device (e.g., a microcontroller) having a configuration. In the configuration, for example, a processor such as a CPU, various storage devices such as RAM and ROM, and peripheral circuits such as a counter (timer), an A/D conversion circuit, a D/A conversion circuit, a clock generation circuit, and an input/output I/F circuit are connected to each other via a bus or a dedicated line. Further, the control circuit 1 may include the differential voltage detection circuit 15 configured as an analog circuit, as described below.

The motor drive control device 10 may have a configuration. In the configuration, at least a part of the control circuit 1 and at least a part of the drive circuit 2 are packaged as one integrated circuit device (IC), or the control circuit 1 and the drive circuit 2 are separately packaged as individual integrated circuit devices.

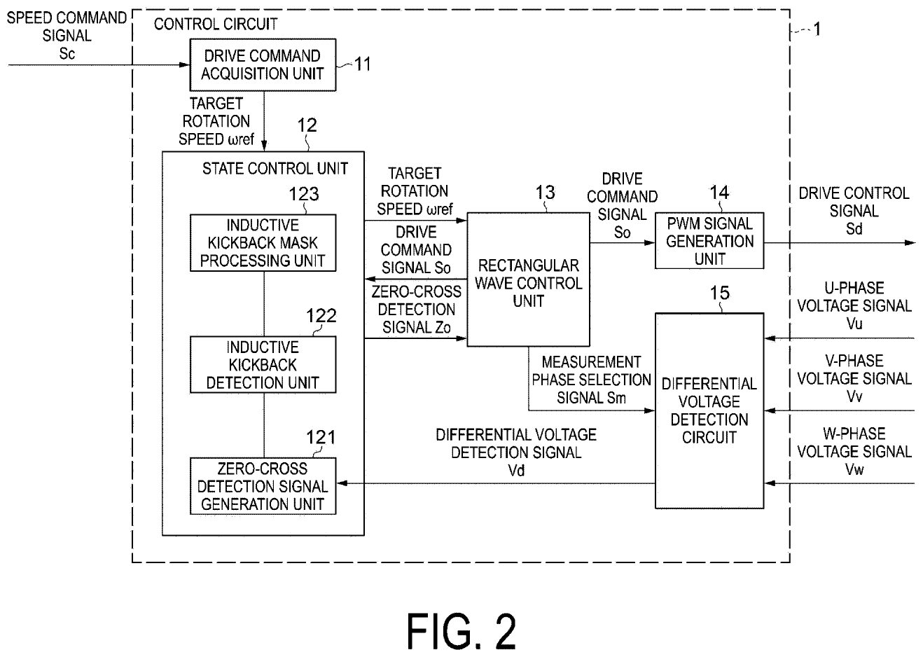

FIG. 2 is a diagram illustrating a functional block configuration of the control circuit 1 in the motor drive control device 10 according to the embodiment.

As illustrated in FIG. 2, the control circuit 1 includes, for example, a drive command acquisition unit 11, a state control unit 12, a rectangular wave control unit 13, a PWM signal generation unit 14, the differential voltage detection circuit 15, as functional blocks for generating the drive control signal Sd in driving the motor by a 120-degree energization rectangular wave drive method. Further, as described below, the state control unit 12 includes a zero-cross detection signal generation unit 121, an inductive kickback detection unit 122, and an inductive kickback mask processing unit 123 as functional blocks for outputting a zero-cross detection signal Zo to the rectangular wave control unit 13 only at necessary timings.

These functional blocks are achieved, for example, at a program processor as the control circuit 1, by the processor executing various arithmetic operations according to a program stored at a memory and controlling peripheral circuits such as a counter and an A/D conversion circuit.

The drive command acquisition unit 11 receives the speed command signal Sc from the outside and analyzes the received speed command signal Sc to acquire a value specifying a target operation state of the motor 3 specified by the speed command signal Sc.

The speed command signal Sc includes a value designating a target operation state of the motor 3. The speed command signal Sc is a signal output from a higher-level device for controlling the motor unit 100 provided outside the motor drive control device 10, for example.

In the embodiment, the speed command signal Sc specifies, for example, the rotation speed of the rotor of the motor 3. The speed command signal Sc includes a value ωref of the rotation speed as a target (target rotation speed) of the rotor of the motor 3.

The speed command signal Sc is, for example, a PWM signal having a duty ratio corresponding to a specified target rotation speed ωref. The drive command acquisition unit 11 measures, for example, the duty ratio of the PWM signal of the speed command signal Sc, and outputs the rotation speed corresponding to the measured duty ratio as the target rotation speed ωref.

In driving the motor, the state control unit 12 outputs the target rotation speed ωref unchanged to the rectangular wave control unit 13, and also outputs the zero-cross detection signal Zo generated based on a differential voltage detection signal Vd output from the differential voltage detection circuit 15 described below to the rectangular wave control unit 13 as necessary. The differential voltage detection signal Vd is a signal obtained by comparing a variation of an induced voltage generated in the coil of the non-energized phase with a reference voltage, based on a phase voltage of each phase of the coil.

The state control unit 12 outputs the zero-cross detection signal Zo capable of being detected based on the differential voltage detection signal Vd to the rectangular wave control unit 13 only at a necessary timing, and thus does not output the zero-cross detection signal Zo at a timing when a spike or ringing occurs. This configuration can avoid outputting, to the rectangular wave control unit 13, the zero-cross detection signal Zo due to an erroneous detection of spikes or ringing as a zero-cross. A functional unit for executing such processing will be described below.

In driving the motor, the rectangular wave control unit 13 outputs a drive command signal So to the PWM signal generation unit 14 and outputs a measurement phase selection signal Sm to the differential voltage detection circuit 15. The measurement phase selection signal Sm is a signal for selecting a phase to be detected by the differential voltage detection circuit 15 among the coil phases of the motor. The rectangular wave control unit 13 can select a non-energized phase as the detection target at the differential voltage detection circuit 15.

In driving the motor, the rectangular wave control unit 13 outputs the measurement phase selection signal Sm corresponding to a non-energized phase to the differential voltage detection circuit 15 in order to obtain the switching timing of the 6 energization patterns in the drive control method using a 120-degree rectangular wave, and sets such that the differential voltage detection signal Vd is generated by comparing the induced voltage of the selected non-energized phase with a neutral point voltage (an example of a reference voltage).

In driving the motor, the rectangular wave control unit 13 performs drive control of the motor by generating the drive command signal So from the target rotation speed ωref and the zero-cross detection signal Zo input from the state control unit 12 in accordance with the drive control method using a 120-degree rectangular wave, and outputting the drive command signal So to the PWM signal generation unit 14. The zero-cross detection signal Zo is a signal indicating the detection timing of the zero-cross to be used for the energization switching generated by the state control unit 12.

Thus, the rectangular wave control unit 13 energizes the windings from the U-phase to the V-phase by one-phase excitation, and causes the differential voltage detection circuit 15 to measure the differential voltage between the induced voltage (phase voltage) generated in the W-phase of the non-energized phase and the neutral point voltage (reference voltage), and to generate the differential voltage detection signal Vd. The rectangular wave control unit 13 outputs to the PWM signal generation unit 14 the drive command signal So adjusted to perform energization switching using the zero-cross detection signal Zo indicating the detection timing of a zero-cross generated by the state control unit 12 based on the generated differential voltage detection signal Vd, thereby performing drive control of the motor. At this time, the DC power supply Vin/2 may be used instead of a voltage obtained by synthesizing the phase voltages of all phases, as a neutral point voltage used as a reference voltage. The rectangular wave control unit 13 may also include a PWM cycle timer Tpwm for adjusting the switching timing of the drive signal of the PWM drive phase and an energization switching timer Tsector for adjusting the energization switching timing.

The energization switching timer Tsector is a timer reset every time energization is switched, and is used for measuring the time from energization switching to zero-cross detection and the energized phase switching time from zero-cross detection to next energization switching, because energization switching is performed at a timing of an electric angle of 60 degrees and the time from energization switching to zero-cross detection is an electric angle of 30 degrees. When the motor is rotating at a high speed, once energization switching is performed after waiting for a time of an electric angle of 30 degrees, there is a possibility that the optimal energization switching timing of the rotor may be delayed, so that energization switching may be performed by subtracting a time for advance angle corresponding to the rotation speed from the energized phase switching time of an electric angle of 30 degrees. The energization switching timer Tsector may also be used for measuring the period between the previous zero-cross and the current zero-cross. That is, the energization switching timer Tsector may be used for measuring the period between zero-cross detections. Although not specifically illustrated in FIG. 2, the rectangular wave control unit 13 may further include a functional unit for executing such processing. The rectangular wave control unit 13 also outputs the drive command signal So to the state control unit 12 in order to execute the mask processing described below.

When the motor is driven, the PWM signal generation unit 14 generates the drive control signal Sd in accordance with the drive command signal So received from the rectangular wave control unit 13, and outputs the drive control signal Sd to the drive circuit 2, thereby performing PWM control of the drive circuit 2.

The differential voltage detection circuit 15 is configured to output the phase voltage of the selected phase to the zero-cross detection signal generation unit 121 as a differential voltage detection signal Vd.

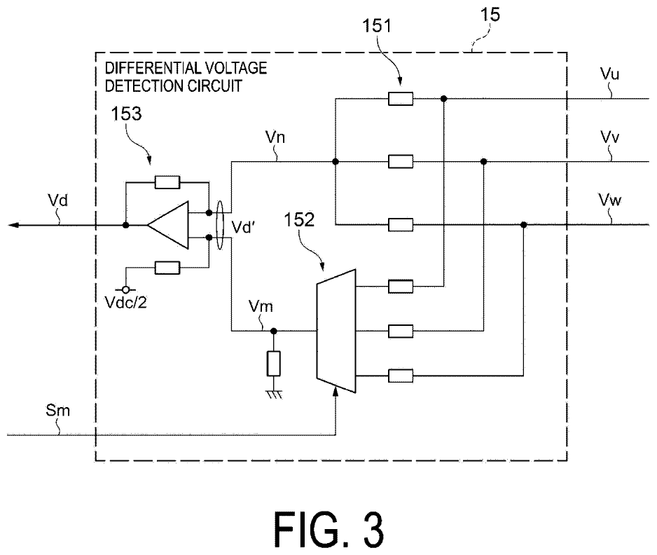

FIG. 3 is a diagram illustrating a configuration example of the differential voltage detection circuit 15. Here, a configuration example of the differential voltage detection circuit 15 will be described.

The differential voltage detection circuit 15 receives the phase voltage signals Vu, Vv, and Vw of the respective phases and the measurement phase selection signal Sm, and outputs the differential voltage detection signal Vd. The differential voltage detection circuit 15 includes plural resistance elements 151 for DC current limitation and voltage adjustment, a measurement phase selection multiplexer (MUX) 152, and a differential amplifier circuit 153. The differential voltage detection circuit 15 demultiplexes the inputs of the phase voltage signals Vu, Vv and Vw of the respective phases into two paths. One path is combined as a composite signal (neutral point voltage) Vn and then the composite signal is input to the differential amplifier circuit 153, and the other path of the demultiplexed inputs is input to a measurement phase selection multiplexer 152. The output from the measurement phase selection multiplexer 152 is also input to the differential amplifier circuit 153. At this time, the resistance elements 151 are set so that the voltage dividing ratio of each phase voltage and the voltage dividing ratio of the corresponding neutral point voltage have the same ratio. When delay circuits are included, the time constant of each phase voltage and the time constant of the corresponding neutral point voltage are set to be the same value.

In the differential voltage detection circuit 15, the measurement phase selection multiplexer 152 selects any one of the 3 phase voltage signals Vu, Vv, and Vw according to the measurement phase selection signal Sm input from the rectangular wave control unit 13, and outputs the selected phase voltage signal as a selected phase voltage signal Vm to the differential amplifier circuit 153. The differential amplifier circuit 153 receives a voltage corresponding to the phase voltage of the selected phase and a composite signal Vn of the 3 phase voltage signals Vu, Vv, and Vw, corresponding to the neutral point voltage of the coil of the motor. That is, the differential amplifier circuit 153 receives a signal corresponding to the differential voltage detection signal Vd′. The differential voltage detection signal Vd′ generated from the selected phase voltage signal Vm and the neutral point voltage Vn has both positive and negative polarities when the motor is driven. Thus, the differential amplifier circuit 153 expands and contracts (amplifies and reduces) the generated signal and shifts the DC power supply Vdc/2, and outputs the shifted signal as the differential voltage detection signal Vd substantially similar to the differential voltage detection signal Vd′ and saturated in the voltage range from 0 V to Vdc with Vdc/2 as the center. That is, the differential voltage detection signal Vd is a signal corresponding to the phase voltage of the selected phase.

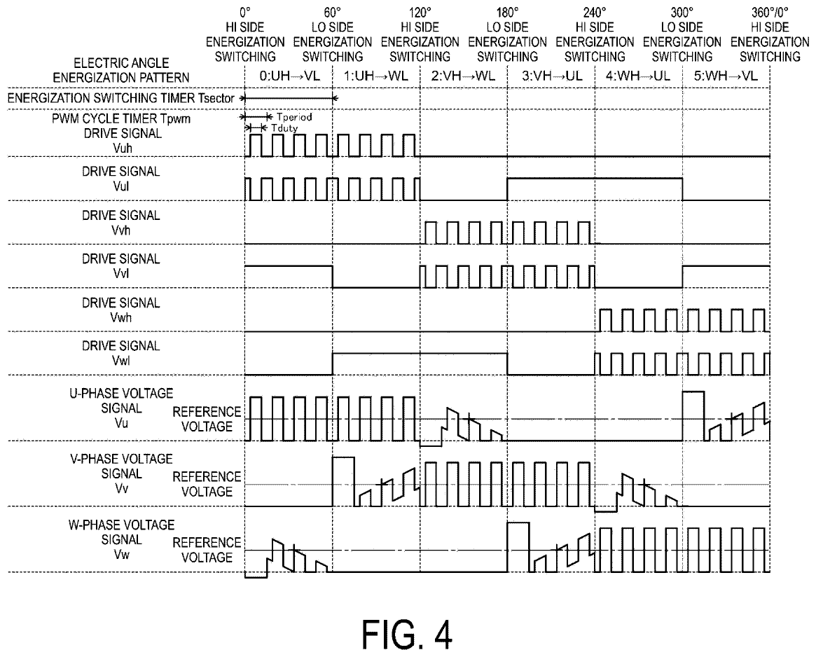

FIG. 4 is a timing chart for describing detection of a zero-cross in the motor drive control device 10 according to the embodiment.

In FIG. 4, waveforms of the drive signals Vuh, Vul, Vvh, Vvl, Vwh, and Vwl generated in the pre-drive circuit 2b corresponding to the drive control signal Sd generated by the PWM signal generation unit 14 of the control circuit 1 are illustrated in electric angles and energization patterns, respectively. In these lower stages, waveforms of the phase voltage signals generated in respective phases of the coils Lu, Lv, and Lw of the motor 3 and waveforms of ½ of the power supply voltage as a reference voltage, are illustrated. The waveforms of the phase voltage signals illustrated in this drawing are not actually measured in the motor drive control device 10 according to the present embodiment illustrated in FIGS. 1 and 2, but are theoretically generated phase voltages. That is, this timing chart illustrates the relationship with the phase voltage signals Vu, Vv, and Vw theoretically generated in the respective phases Lu, Lv, and Lw of the coils of the motor 3 when the drive signals Vuh, Vul, Vvh, Vvl, Vwh, and Vwl of the respective phases are switched based on the drive control signal Sd.

In FIG. 4, each energization pattern for each electric angle of 60 degrees is counted by an energization switching timer Tsector. The drive signal generated in the pre-drive circuit 2b is controlled by a center-aligned PWM drive via a PWM cycle timer Tpwm counted for each PWM cycle in the rectangular wave control unit 13, and is driven by a PWM cycle Tperiod and a duty Tduty. At this time, the duty ratio of the drive signal becomes Tduty/Tperiod. In FIGS. 4, ½ of the power supply voltage is used as the reference voltage. When the neutral point voltage obtained by combining the respective phase voltages is used as the reference voltage, the neutral point voltage varies due to the energization on/off of the energized phase by the on/off of the PWM drive phase, so that the reference voltage also varies. However, the reference voltage at the time of zero-cross during energization on is same between the neutral point voltage and ½ of the power supply voltage.

The control circuit 1 generates the drive control signal Sd, as the differential voltage between the induced voltage and the reference voltage, while switching between the energized phases according to the zero-cross of the differential voltage signal Vd. Specifically, the control circuit 1 generates the drive control signal Sd adjusted to energize from the coil Lu to the coil Lv between the electric angles of 0 degrees and 60 degrees. Then, the control circuit 1 switches between the energized phases at the electric angle of 60 degrees (LO side energization switching), and generates the drive control signal Sd adjusted to energize from the coil Lu to the coil Lw between the electric angles of 60 degrees and 120 degrees.

During this timing, as illustrated in FIG. 4, while the drive signals Vuh and Vul are switched complementarily, the drive signal Vvl is switched to high between the electric angles of 0 degrees and 60 degrees, and then the drive signal Vwl is switched to high between the electric angles of 60 degrees and 120 degrees. In this case, the W phase is the non-energized phase between the electric angles of 0 degrees and 60 degrees, and the V phase is the non-energized phase between the electric angles of 60 degrees and 120 degrees.

Next, the control circuit 1 switches between the energized phases at an electric angle of 120 degrees (HI side energization switching), generates the drive control signal Sd adjusted to energize from the coil Lv to the coil Lw between electric angles of 120 degrees and 180 degrees, switches between the energized phases at an electric angle of 180 degrees (LO side energization switching), and generates the drive control signal Sd adjusted to energize from the coil Lv to the coil Lu between electric angles of 180 degrees and 240 degrees. The HI side energization switching is energization switching to switch between the energized phases at the power supply side, and the LO side energization switching is energization switching to switch between the energized phases at the GND side.

During this timing, as illustrated in FIG. 4, while the drive signals Vvh and Vvl are switched complementarily, the drive signal Vwl is switched high between the electric angles of 120 degrees and 180 degrees, and then the drive signal Vul is switched high between the electric angles of 180 degrees and 240 degrees. In this case, the U phase is a non-energized phase between the electric angles of 120 degrees and 180 degrees, and the W phase is a non-energized phase between the electric angles of 180 degrees and 240 degrees.

Further, the control circuit 1 switches between the energized phases at the electric angle of 240 degrees (HI side energization switching) to generate the drive control signal Sd adjusted to energize from the coil Lw to the coil Lu between the electric angles of 240 degrees and 300 degrees, and switches between the energized phases at the electric angle of 300 degrees (LO side energization switching) to generate the drive control signal Sd adjusted to energize from the coil Lw to the coil Lv between the electric angles of 300 degrees and 360 degrees.

During this timing, as illustrated in FIG. 4, while the drive signals Vwh and Vwl are switched complementarily, the drive signal Vul is switched high between the electric angles of 240 degrees and 300 degrees, and then the drive signal Vvl is switched high between the electric angles of 300 degrees and 360 degrees. In this case, the V phase is a non-energized phase between the electric angles of 240 degrees and 300 degrees, and the U phase is a non-energized phase between the electric angles of 300 degrees and 360 degrees.

Further next, the control circuit 1 switches between the energized phases at the electric angle of 360 degrees (HI side energization switching), and returns to the original electric angle.

In this way, the control circuit 1 generates the drive control signal Sd while switching between the energized phases, and drives the motor so that the rotor of the motor rotates over the electric angle of 360 degrees.

As illustrated in FIG. 4, when the motor 3 rotates according to the drive control signal Sd generated by the PWM signal generation unit 14 of the control circuit 1, the phase voltage signal of the energized phase becomes 2 values of the power supply voltage or zero, while the phase voltage signal of the non-energized phase gradually varies with the rotation of the motor. This is because an induced voltage that varies according to the rotational position of the rotor of the motor is generated in the non-energized phase, and the induced voltage of the non-energized phase indicates the rotational position of the rotor of the motor 3. As is clear from FIG. 4, when the rotor of the motor 3 rotates ideally, the induced voltage of the non-energized phase coincides with the reference voltage at a predetermined timing. Thus, the rotor of the motor 3 can be found to rotate ideally by detecting the timing, as a zero-cross, with the differential voltage between the induced voltage of the non-energized phase and the reference voltage becoming zero and switching between the energized phases of the motor using the detection timing of the zero-cross. On the other hand, when the occurrence and resolution of the inductive kickback, or the spike or ringing are erroneously detected as a zero-cross used for the energization switching, the drive control signal Sd is output so as to switch the energization earlier than originally intended, and the rotation speed of the motor may become unstable or the rotation speed of the motor may become high and the power consumption per rotation speed may deviate from the optimum state.

In the motor drive control device 10 of the present embodiment, the zero-cross detection signal Zo is output to the rectangular wave control unit 13 only at necessary timings by mask processing, thereby avoiding a situation with an adverse effect exerted on the drive of the motor.

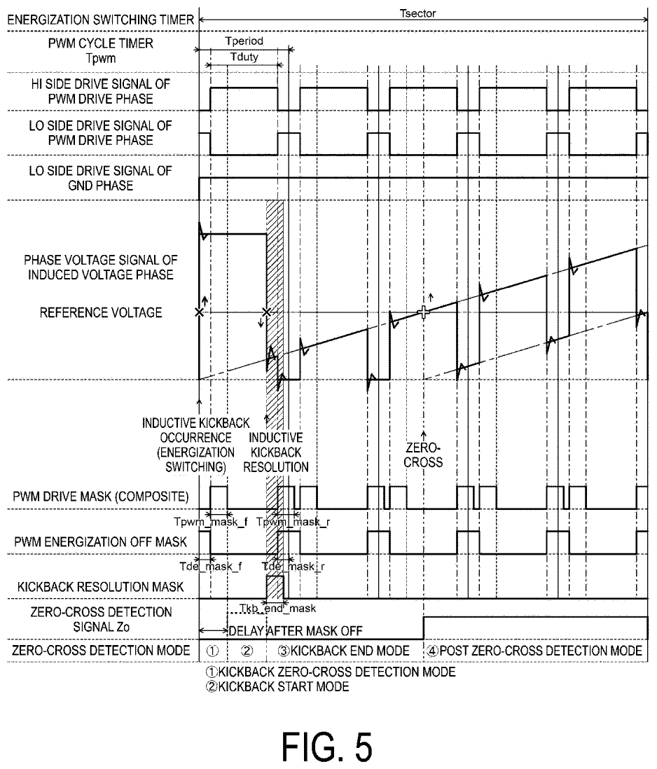

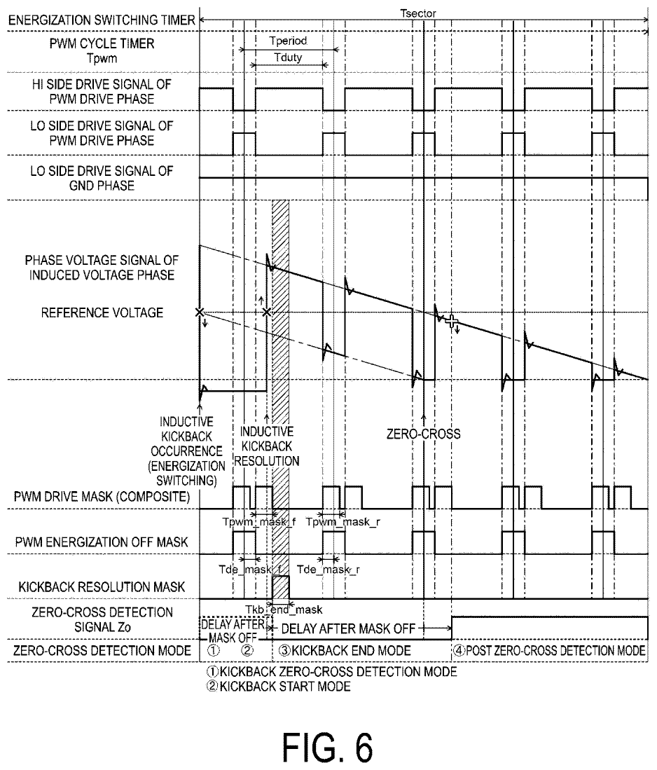

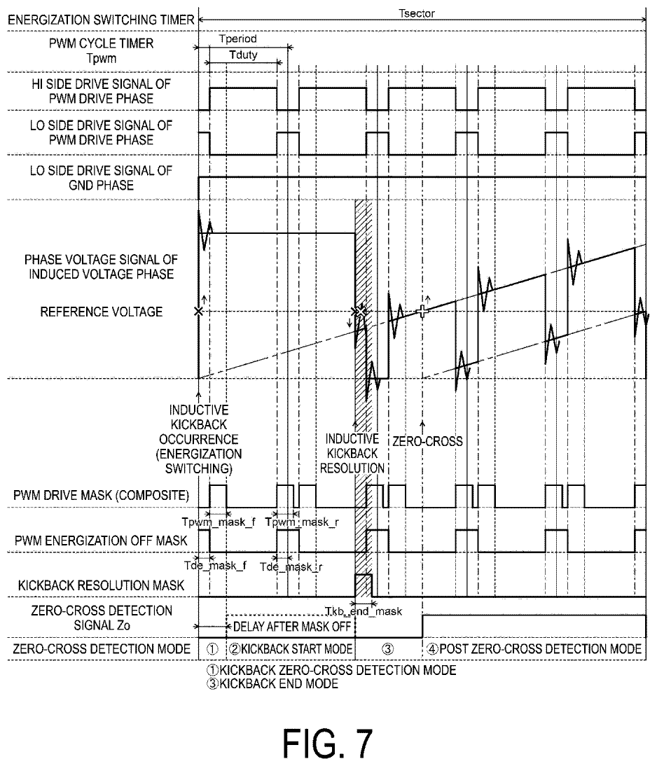

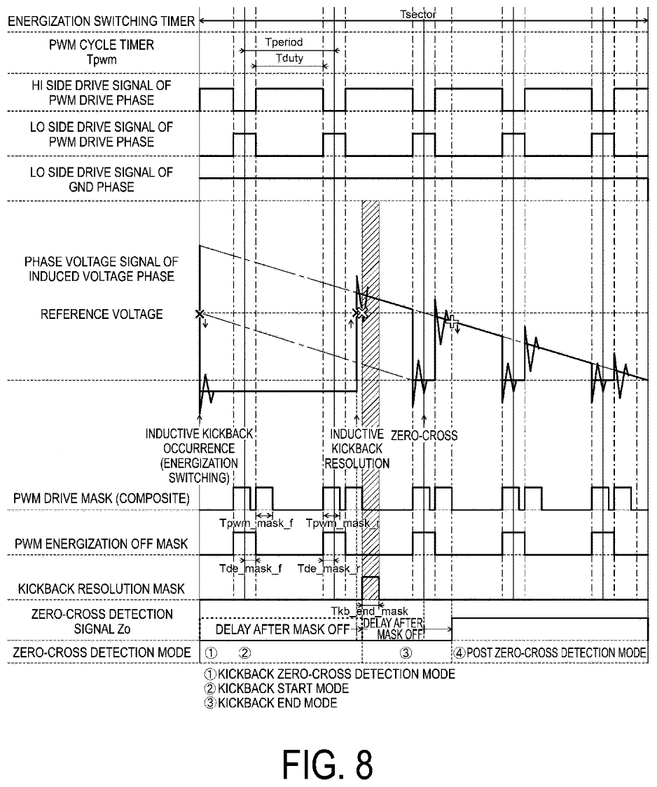

FIGS. 5 to 8 are timing charts for describing the timing of the kickback resolution mask according to the embodiment. FIGS. 5 and 6 illustrate an example with the time from the occurrence to the resolution of the inductive kickback relatively short due to a low load. FIGS. 7 and 8 illustrate an example with the time from the occurrence to the resolution of the inductive kickback relatively long due to a high load. The inductive kickback is a spike-like rise or fall of the induced voltage generated in the non-energized phase accompanying the switching of the energized phase.

In FIGS. 5 to 8, from the top, there are illustrated: waveforms of drive signals at the HI side of the PWM drive phase in the energization switching Tsector and the PWM cycle timer Tpwm; waveforms of drive signals at the LO side of the PWM drive phase; waveforms of drive signals at the LO side of the GND phase; waveforms of phase voltage signals of the induced voltage phase; PWM drive masks (composite) Tpwm_mask_f and Tpwm_mask_r to be described below; PWM energization off masks Tde_mask_f and Tde_mask_r; kickback resolution mask Tkb_end_mask; zero-cross detection signal Zo; and zero-cross detection mode. The HI side and the LO side of the PWM drive phase (energized phase) are the same phase and are switched complementarily in this example. The PWM drive mask (composite) and the PWM energization off mask are illustrated separately for the first half and the second half of the center-aligned PWM.

In FIGS. 5 to 8, the drive signals of the HI side and of the LO side of the PWM drive phase at the power supply side of the energized phase are switched complementarily, and the drive signal of the LO side of the GND phase at the GND side of the energized phase is high. FIGS. 5 and 7 are examples when the energized phase is switched to another energized phase by the GND phase switching at the GND side of the energized phase (LO side energization switching), and FIGS. 6 and 8 are examples when the energized phase is switched to another energized phase by the PWM drive phase switching at the power supply side of the energized phase (HI side energization switching). As in FIGS. 4, ½ of the power supply voltage is used as the reference voltage in FIGS. 5 to 8.

As illustrated in FIGS. 5 and 7, when the energized phase is switched to another energized phase by the GND phase switching at the GND side of the energized phase (LO side energization switching), an inductive kickback occurs in the power supply direction, an induced voltage appears after the inductive kickback is resolved, and the induced voltage gradually increases. As illustrated in FIGS. 6 and 8, when the energized phase is switched to another energized phase by the PWM drive phase switching at the power supply side of the energized phase (HI side energization switching), an inductive kickback occurs in the GND direction, an induced voltage appears after the inductive kickback is resolved, and the induced voltage gradually decreases.

In either drawing, when the energized phase is switched to another energized phase, an inductive kickback immediately occurs in the non-energized phase. Regardless of the length of time between the occurrence and resolution of the inductive kickback, spikes and ringing are found to occur in the non-energized phase for a while after the inductive kickback is resolved. Furthermore, spikes and ringing are found to occur each time the drive signal for the PWM drive phase of the energized phase is switched to another drive signal.

In the zero-cross detection mask time in the related art, the occurrence of the zero-cross detection signal Zo is masked every time the drive signal for the PWM drive phase of the energized phase is switched to another drive signal. The time for performing the masking associated with the drive signal for the PWM drive phase of the energized phase is referred to as a second mask time (PWM drive mask). This configuration can avoid erroneously detecting spikes and ringing as a zero-cross used for energization switching. These spikes and ringing are generated in association with the switching on and off of the switch due to the switching of the drive signal for the PWM drive phase of the energized phase.

In the control circuit 1 of the motor drive control device 10 of the present embodiment, in addition to the second mask time, the state control unit 12 masks the occurrence of the zero-cross detection signal Zo for a while after the inductive kickback is resolved. The period for performing the masking associated with the resolution of the inductive kickback is referred to as a first mask time (kickback resolution mask). This configuration can avoid erroneously detecting spikes and ringing as a zero-cross used for energization switching. These spikes and ringing are generated in association with the resolution of the inductive kickback not synchronous with the drive signal of the PWM drive phase. The first mask time (kickback resolution mask) is a period indicated by a hatched portion in FIGS. 5 to 8.

As described above, in the control circuit 1 of the motor drive control device 10 of the present embodiment, the zero-cross detection signal Zo is output to the rectangular wave control unit 13 only at a necessary timing by performing the mask processing over both the first mask time and the second mask time.

The control circuit 1 of the motor drive control device 10 of the present embodiment detects the occurrence and resolution of the inductive kickback based on the differential voltage detection signal Vd generated from the induced voltage of the non-energized phase, so that the inductive kickback can be detected with high accuracy.

The configuration of a functional unit for outputting the zero-cross detection signal Zo to the rectangular wave control unit 13 only at a necessary timing in the state control unit 12 will be described. This functional unit is achieved by the zero-cross detection signal generation unit 121, the inductive kickback detection unit 122, and the inductive kickback mask processing unit 123.

The zero-cross detection signal generation unit 121 generates the zero-cross detection signal Zo indicating that the zero-cross is detected based on the differential voltage detection signal Vd. The zero-cross detection signal generation unit 121 receives the differential voltage detection signal Vd, detects as a zero-cross when the differential voltage detection signal Vd becomes a predetermined value in a predetermined variation detection direction, and generates the zero-cross detection signal Zo. The predetermined value is, for example, “zero (0)”.

The zero-cross detection signal generation unit 121 may detect a variation of the differential voltage detection signal Vd by using the differential voltage detection signal Vd as a digital signal, and detect a zero-cross when the value of the differential voltage detection signal Vd becomes “zero”, or may be configured to determine a zero-cross by comparing the differential voltage detection signal Vd as an analog signal with a voltage value corresponding to a zero-cross by using a comparator, for example. Further, the differential voltage detection signal Vd as an analog signal may be compared with a voltage value corresponding to a zero-cross by using an A/D converter to determine a zero-cross. Alternatively, the selected phase voltage signal Vm as an induced voltage, and the neutral point voltage Vn are digitized and compared to determine a zero-cross.

The zero-cross detection signal generation unit 121 masks the occurrence of the zero-cross detection signal Zo over a second predetermined time at the rise and fall timing of the rectangular wave signal by the drive command signal So input from the rectangular wave control unit 13 to the state control unit 12. The second predetermined time is set to be a sufficient period for spikes and ringing generated with the switching of the PWM signal to stop.

The zero-cross detection signal generation unit 121 includes a PWM drive mask timer for counting the second mask time in order to determine whether to execute the mask processing in the second mask time (PWM drive mask). The zero-cross detection signal generation unit 121 executes the mask processing and does not generate the zero-cross detection signal Zo while the time counted by the PWM drive mask timer corresponds to the time within the second mask time. On the other hand, the zero-cross detection signal generation unit 121 generates the zero-cross detection signal Zo without executing the mask processing while the time counted by the PWM drive mask timer corresponds to the time except the second mask time. In addition to the second mask time (PWM drive mask), the zero-cross detection signal generation unit 121 may execute mask processing during the mask time (PWM energization off mask) of the energization off period of the energized phase, with the HI side of the PWM drive phase being low, by using a PWM mask timer described below.

By performing mask processing during the second mask time, the zero-cross detection signal generation unit 121 masks the generation of the zero-cross detection signal Zo over the second predetermined time at the on-off timing of the switches of the PWM drive phase in the energized phase among the high-side switches and the low-side switches of the inverter circuit 2a.

When a zero-cross occurs during the mask period caused by the PWM drive mask or the PWM energization off mask and the mask is resolved after the lapse of the mask period, once the post zero-cross state is maintained (that is, after the differential voltage signal Vd representing the differential voltage between the induced voltage and the reference voltage once becomes zero and then changes the polarity, the state after the polarity change is maintained), the zero-cross detection signal generation unit 121 determines that a zero-cross has occurred, and generates the zero-cross detection signal Zo with a delay. On the other hand, when a zero-cross having occurred during the mask period is released and the mask is resolved after the lapse of the mask period, once the zero-cross state is resolved (that is, after the differential voltage signal Vd representing the differential voltage between the induced voltage and the reference voltage, once becomes zero and then returns to the state before the polarity change), the zero-cross is regarded as not having occurred, and the zero-cross detection signal Zo is not generated.

The inductive kickback detection unit 122 monitors the zero-cross detection signal Zo input from the zero-cross detection signal generation unit 121, and determines the occurrence and resolution of inductive kickback generated at the coil of a non-energized phase after switching between the energized phases to the coil, as well as the zero-cross to be used for energization switching. The inductive kickback detection unit 122 then notifies the inductive kickback mask processing unit 123 of the timing of the detected occurrence and resolution of the inductive kickback and the timing of the zero-cross to be used for energization switching.

The inductive kickback detection unit 122 monitors the zero-cross detection signal Zo generated at the zero-cross detection signal generation unit 121 to determine the occurrence and resolution of the inductive kickback and the zero-cross used for energization switching. The inductive kickback detection unit 122 monitors the zero-cross detection signal Zo generated by the zero-cross detection signal generation unit 121, and determines the occurrence and resolution of the inductive kickback and the zero-cross to be used for the energization switching according to the generation order of the zero-cross detection signal Zo from the energization switching.

The zero-cross detection signal generation unit 121 switches the variation detection direction (comparator detection direction) of the differential voltage detection signal Vd from negative to positive or from positive to negative, depending on whether the occurrence or the resolution of inductive kickback is to be detected in the energization pattern. For example, as illustrated in FIGS. 5 and 7, when the energized phase is switched to another energized phase by the GND phase switching at the GND side of the energized phase (LO side energization switching), the variation detection direction of the differential voltage detection signal Vd when the inductive kickback occurs, is from negative to positive, and the variation detection direction of the differential voltage detection signal Vd when the inductive kickback is resolved, is from positive to negative. On the other hand, as illustrated in FIGS. 6 and 8, when the energized phase is switched to another energized phase by the PWM drive phase switching at the power supply side of the energized phase (HI side energization switching), the variation detection direction of the differential voltage detection signal Vd when the inductive kickback occurs, is from positive to negative, and the variation detection direction of the differential voltage detection signal Vd when the inductive kickback is resolved, is from negative to positive. The zero-cross detection signal generation unit 121 sequentially generates the zero-cross detection signal Zo due to the occurrence and resolution of the kickback by switching the variation detection direction.

After detecting the occurrence and resolution of the inductive kickback, the inductive kickback detection unit 122 detects a zero-cross used for energization switching by switching the variation detection direction (comparator detection direction) of the differential voltage detection signal Vd from negative to positive or from positive to negative. For example, as illustrated in FIGS. 5 and 7, when the energized phase is switched to another energized phase by the GND phase switching at the GND side of the energized phase (LO side energization switching), the variation detection direction of the differential voltage detection signal Vd is switched from negative to positive to detect a zero-cross used for energization switching. On the other hand, as illustrated in FIGS. 6 and 8, when the energized phase is switched to another energized phase by the PWM drive phase switching at the power supply side of the energized phase (HI side energization switching), the variation detection direction of the differential voltage detection signal Vd is switched from positive to negative to detect a zero-cross used for energization switching. The zero-cross detection signal generation unit 121 sequentially generates the zero-cross detection signal Zo by detecting a zero-cross used for energization switching after kickback occurrence and kickback resolution by switching the variation detection direction.

An inductive kickback detection unit 122 does not output the zero-cross detection signal Zo determined to be either kickback occurrence or kickback resolution to the rectangular wave control unit 13 and performs cancellation processing, as illustrated by dotted line in a timing chart illustrating the zero-cross detection signal Zo of FIGS. 5 to 8. The output of the zero-cross detection signal Zo by zero-cross detection used for energization switching is not affected by the cancellation processing.

The state control unit 12 sets a plurality of zero-cross detection modes when detecting a zero-cross used for kickback occurrence, kickback resolution, and energization switching. The plurality of zero-cross detection modes are, for example, a kickback zero-cross detection mode, a kickback start mode, a kickback end mode, and a post zero-cross detection mode. The kickback zero-cross detection mode is set when the occurrence of the inductive kickback or the zero-cross used for energization switching is under detection by energization switching. The kickback start mode is set when the resolution of the inductive kickback is under detection by the detection of the occurrence of the inductive kickback. The kickback end mode is set when the zero-cross used for energization switching is under detection by the resolution of the inductive kickback. The post zero-cross detection mode is set, by the detection of the zero-cross, until the next energization switching. When the inductive kickback is generated, a kickback zero-cross detection mode, a kickback start mode, a kickback end mode, and a post zero-cross detection mode are sequentially set. When the inductive kickback does not occur or when the duration of the inductive kickback is extremely short, a post zero-cross detection mode is set after the kickback zero-cross detection mode.

The state control unit 12 utilizes a timer (energization switching timer) for measuring the time from the energization switching of the rectangular wave control unit 13, and measures the respective detection times from the energization switching for the zero-cross used for kickback occurrence, kickback resolution, and energization switching detected by the zero-cross detection signal generation unit 121 and determined by the inductive kickback detection unit 122.

In the energization switching, the inductive kickback may not occur or the time from the occurrence of the inductive kickback to the resolution may be extremely short due to a low load, and thereby the zero-cross due to the occurrence of the inductive kickback may not be detected. In this case, without detecting the zero-cross by the occurrence of the inductive kickback, the zero-cross between the induced voltage used for energization switching and the reference voltage is generated in a fixed time range by the characteristics of the motor in the elapsed time centering on the electric angle of 30 degrees from the immediately preceding energization switching. Both the zero-cross due to the occurrence of the inductive kickback and the zero-cross used for energization switching have the same direction with the sign of the differential voltage between the induced voltage and the reference voltage changing, so that distinguishing both the zero-crosses is important.

On the other hand, when the time from the occurrence of the inductive kickback to the resolution is sufficiently long, the zero-cross due to the occurrence of the inductive kickback occurs immediately after the energization switching. At this time, the zero-cross generated during the mask period by the PWM drive mask or the PWM energization off mask is detected (after the occurrence of the actual zero-cross) due to maintaining the zero-cross state when the mask is resolved after the elapse of the mask period. On the other hand, zero-cross due to the occurrence of the inductive kickback can be detected within the elapsed time from the energization switching to 1 cycle of the PWM drive, because there exists a period with the zero-cross not masked by the PWM drive mask or the PWM energization off mask between the energization switching and 1 cycle of the PWM drive, although the start timing of the PWM cycle is not synchronized with the energization switching.

In either of these cases, the zero-cross due to the inductive kickback occurrence and the zero-cross used for energization switching can be determined by using the elapsed time from the immediately preceding energization switching to the occurrence of the first zero-cross, instead of the direction with the sign of the differential voltage between the induced voltage and the reference voltage changes.

When the state control unit 12 is set to the kickback zero-cross detection mode, the inductive kickback detection unit 122 executes determination processing of the kickback zero-cross when detecting the zero-cross detection signal Zo generated by the zero-cross detection signal generation unit 121. That is, the inductive kickback detection unit 122 executes determination processing of whether the detected zero-cross is caused by the kickback occurrence or the zero-cross used for energization switching based on the detection timing of the zero-cross detection signal Zo in the kickback zero-cross detection mode.

Specifically, the inductive kickback detection unit 122 executes determination processing of the kickback zero-cross. When the detection timing of the zero-cross detection signal Zo is within a specified value of the elapsed time from energization switching, the zero-cross is determined as the occurrence of the kickback. On the other hand, when the detection timing of the zero-cross detection signal Zo is not within a specified value of the elapsed time from energization switching, the zero-cross is determined as the zero-cross used for energization switching.

The inductive kickback detection unit 122 executes kickback occurrence detection processing when determining the occurrence of the kickback. That is, the inductive kickback detection unit 122 shifts the state control unit 12 to the kickback start mode and notifies the inductive kickback mask processing unit 123 of the occurrence of the inductive kickback.

When the state control unit 12 is set to the kickback start mode, the inductive kickback detection unit 122 determines that the kickback is resolved and performs kickback resolution detection processing when the zero-cross detection signal Zo generated by the zero-cross detection signal generation unit 121 is detected. That is, the inductive kickback detection unit 122 shifts the state control unit 12 to the kickback end mode and notifies the inductive kickback mask processing unit 123 of the resolution of the inductive kickback.

The inductive kickback detection unit 122 performs zero-cross detection processing, when the state control unit 12 is set to the kickback zero-cross detection mode and then the zero-cross for energization switching is determined by the kickback zero-cross determination processing, or when the kickback end mode is set and then the zero-cross detection signal Zo is detected. That is, the inductive kickback detection unit 122 shifts the state control unit 12 to the post zero-cross detection mode and notifies the inductive kickback mask processing unit 123 of the detection of the zero-cross used for energization switching.

As described above, when the state control unit 12 is set to the kickback zero-cross detection mode or the kickback start mode and the occurrence and resolution of the inductive kickback are detected by detecting the zero-cross detection signal Zo, the inductive kickback detection unit 122 notifies the inductive kickback mask processing unit 123 of the occurrence and resolution of the detected inductive kickback and the timing of the zero-cross used for energization switching.

When processing the new zero-cross detection signal Zo as the zero-cross used for energization switching after shifting the state control unit 12 to the kickback end mode, the inductive kickback mask processing unit 123 performs processing for masking the output of the zero-cross detection signal Zo over a predetermined period. The processing for masking the output of the zero-cross detection signal Zo may be processing for not outputting the zero-cross detection signal Zo generated by the zero-cross detection signal generation unit 121 to the rectangular wave control unit 13 due to the occurrence of spikes and ringing caused by the inductive kickback resolution.

The inductive kickback mask processing unit 123 masks the output of the zero-cross detection signal Zo over a first predetermined time after the inductive kickback detection unit 122 detects the resolution of the inductive kickback. A sufficient period for stopping ringing generated after the resolution of the inductive kickback is set as the first predetermined time. The first predetermined time and the second predetermined time use the same length of time, but may be independent times defined separately.

The inductive kickback mask processing unit 123 includes a kickback resolution mask timer for determining whether to execute the mask processing during the first mask time (kickback resolution mask). The kickback resolution mask timer counts the first mask time when receiving the notification of the resolution of the inductive kickback detected by the inductive kickback detection unit 122. The inductive kickback mask processing unit 123 executes the mask processing while the period counted by the kickback resolution mask timer corresponds to the first mask time, and does not output the zero-cross detection signal Zo generated by the zero-cross detection signal generation unit 121 to the rectangular wave control unit 13. On the other hand, the inductive kickback mask processing unit 123 does not execute the mask processing while the time counted by the kickback resolution mask timer does not correspond to the first mask time, and outputs the zero-cross detection signal Zo generated by the zero-cross detection signal generation unit 121 to the rectangular wave control unit 13.

In FIG. 5, the occurrence of the inductive kickback in the LO side energization switching is indicated by the first X mark due to the zero-cross between the induced voltage and the reference voltage. This zero-cross is masked from the generation of the zero-cross detection signal Zo by a PWM mask (integration of a PWM drive mask (composite) and a PWM energization off mask). In this case, the induced voltage becomes larger than the reference voltage, so that the zero-cross detection signal Zo is generated at a timing delayed after the mask is released, and is used to detect the occurrence of the kickback in the inductive kickback detection unit 122.

The resolution of the inductive kickback is indicated by the second X mark due to the zero-cross between the induced voltage and the reference voltage, and the zero-cross detection signal Zo is generated at this timing, and is used to detect the resolution of the kickback at the inductive kickback detection unit 122.

The zero-cross used for energization switching is within the period when the PWM mask (integrated) is off, and the zero-cross detection signal Zo is generated at a timing indicated by the blank+mark due to the zero-cross between the induced voltage and the reference voltage, and is used to detect the zero-cross used for energization switching in the inductive kickback detection unit 122.

In FIG. 6, the occurrence of the inductive kickback in the HI side energization switching is indicated by the first X mark due to the zero-cross between the induced voltage and the reference voltage, and the zero-cross detection signal Zo is generated at this timing, and is used to detect the occurrence of the kickback at the inductive kickback detection unit 122.

The resolution of the inductive kickback is indicated by the second X mark due to the zero-cross between the induced voltage and the reference voltage. In this zero-cross, the generation of the zero-cross detection signal Zo is masked by the PWM mask (integrated). When the induced voltage becomes larger than the reference voltage, the zero-cross detection signal Zo is generated at a timing delayed after the mask is released, and is used for the detection of the kickback resolution in the inductive kickback detection unit 122. Thus, the start of the kickback resolution mask is delayed.

In the zero-cross used for the energization switching, the generation of the zero-cross detection signal Zo is masked by the PWM mask (integrated), and the PWM mask (integrated) is in an off period, and thus the induced voltage becomes smaller than the reference voltage, so that the zero-cross detection signal Zo is generated at a timing delayed indicated by a blank+mark, and the generated zero-cross detection signal Zo is used for the zero-cross detection used for the energization switching at the inductive kickback detection unit 122.

In FIG. 7, the occurrence of the inductive kickback in the LO side energization switching is indicated by the first X mark due to the zero-cross between the induced voltage and the reference voltage. In this zero-cross, the generation of the zero-cross detection signal Zo is masked by the PWM mask (integrated). When the induced voltage becomes larger than the reference voltage, the zero-cross detection signal Zo is generated at a timing delayed after the mask is released, and is used for the detection of the kickback occurrence in the inductive kickback detection unit 122.

The resolution of the inductive kickback is indicated by the second X mark due to the zero-cross between the induced voltage and the reference voltage, and the zero-cross detection signal Zo is generated at this timing and is used to detect the kickback resolution in the inductive kickback detection unit 122.

In the zero-cross indicated by the blank X mark, the induced voltage becomes larger than the reference voltage, but the output of the zero-cross detection signal Zo is masked by the kickback resolution mask.

The zero-cross used for energization switching is within the period when the PWM mask (integrated) is off, and the zero-cross detection signal Zo is generated at the timing indicated by the blank+mark due to the zero-cross between the induced voltage and the reference voltage, and is used to detect the zero-cross used for energization switching in the inductive kickback detection unit 122.

In FIG. 8, the occurrence of the inductive kickback in energization switching at the HI side is indicated by the first X mark due to the zero-cross between the induced voltage and the reference voltage, and the zero-cross detection signal Zo is generated at this timing and is used to detect the kickback occurrence at the inductive kickback detection unit 122.

The resolution of the inductive kickback is indicated by the second X mark due to the zero-cross between the induced voltage and the reference voltage. In this zero-cross, the generation of the zero-cross detection signal Zo is masked by the PWM mask (integrated). When the induced voltage becomes larger than the reference voltage, the zero-cross detection signal Zo is generated at a timing delayed after the mask is released, and is used for detection of kickback resolution in the inductive kickback detection unit 122. Thus, the start of the kickback resolution mask is delayed.

In the zero-cross indicated by the blank×mark, the induced voltage becomes smaller than the reference voltage, but the output of the zero-cross detection signal Zo is masked by the kickback resolution mask.

The zero-cross used for energization switching is within the period when the PWM mask (integrated) is off, and when the induced voltage becomes smaller than the reference voltage, the zero-cross detection signal Zo is generated at a timing delayed indicated by the blank+mark, and the generated zero-cross detection signal Zo is used for zero-cross detection used for energization switching in an inductive kickback detection unit 122.

Next, the operation of mask processing accompanying rectangular wave switching by the control circuit 1 of the motor drive control device 10 according to the embodiment will be described.

First, a description will be given of a processing flow at the time of mask processing in a PWM mask (integrated) including a second mask time (PWM drive mask) and a mask time during the energization off period of the energized phase (PWM energization off mask).

In this example, PWM mask timers Toffset and Twindow are used for measuring the mask time during a PWM mask (integrated) including a second mask time (PWM drive mask) and a mask time during the energization off period of the energized phase (PWM energization off mask), instead of measuring the mask period using a PWM cycle timer Tpwm for measuring the second mask time (PWM drive mask) and the mask time during the energization off period of the energized phase (PWM energization off mask). The zero-cross detection signal generation unit 121 includes the PWM mask timer.

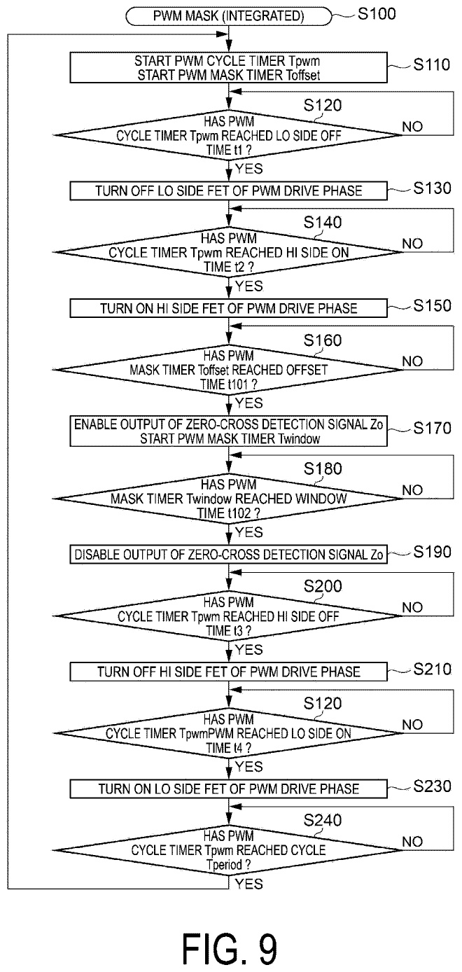

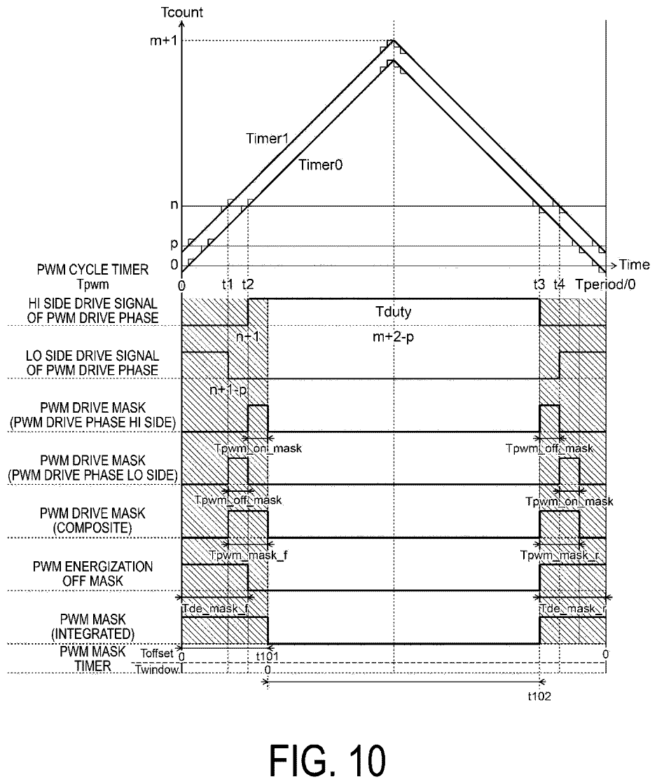

FIG. 9 is a flowchart illustrating an example of a processing flow during mask processing in a PWM mask (integrated) including a second mask time (PWM drive mask) and a mask time (PWM energization off mask) during the energization off period of the energized phase. FIG. 10 is a diagram for describing the timing of a PWM mask (integrated) including a PWM drive mask and a PWM energization off mask.

FIG. 10 illustrates from the top: a triangular wave indicating one PWM cycle of center-aligned PWM drive; a value of a PWM cycle timer Tpwm; a waveform of a drive signal at the HI side of the PWM drive phase (energized phase); a waveform of a drive signal at the LO side of the PWM drive phase (energized phase); and masks associated with rectangular wave switching including: a PWM drive mask (at the HI side of the PWM drive phase); a PWM drive mask (at the LO side of the PWM drive phase); a PWM drive mask (composite) obtained by combining PWM drive mask periods at the HI side of the PWM drive phase and the LO side of the PWM drive phase; a PWM energization off mask; and a PWM mask (integrated) obtained by integrating mask periods associated with rectangular wave switching (PWM drive mask, composite)+PWM energization off mask); and values of PWM mask timers Toffset and Twindow. The PWM drive phase (energized phase) at the HI side and the PWM drive phase (energized phase) at the LO side are of the same phase and are switched complementarily in this example. In this case, in the PWM cycle Tperiod, the period from t1 to t2 and the period from t3 to t4 serve as the dead time, the period from 0 to t1 and the period from t4 to Tperiod serve as the PWM drive phase LO side ON period, and the period from t2 to t3 serves as the PWM drive phase HI side ON period, so that the PWM cycle timer is driven with duty Tduty, and the duty ratio of the drive signal is Tduty/Tperiod.

In this example, the lower triangular wave defines the switching timing of the HI side of the PWM drive phase (energized phase), and the upper triangular wave defines the switching timing of the LO side of the PWM drive phase (energized phase). In this example, two triangular waves are used to provide a dead time at the time of switching with the switching timing shifted to each other, but simultaneously and the switch timing of both PWM energized phases can be complementarily performed by using one triangular wave.

The PWM drive mask is provided with a Tpwm_on_mask used when the switch is turned on and a Tpwm_off_mask used when the switch is turned off, in order to avoid erroneous detection of spikes and ringing occurring in the voltage waveforms of the induced voltage and the reference voltage associated with rectangular wave switching.

A PWM drive mask (composite) Tpwm_mask_f, Tpwm_mask_r, as a combination of the periods of the HI side and the LO side of the PWM drive mask, in the first half of one PWM cycle of center-aligned PWM drive, is a period of time from when the LO side of the PWM drive phase is off until the time of Tpwm_on_mask elapses after when the HI side of the PWM drive phase is on. And in the second half of the PWM cycle, the PWM drive mask (composite) is a period of time from when the HI side of the PWM drive phase is off until the time of Tpwm_on_mask elapses after when the LO side of the PWM drive phase is on.

The PWM energization off mask is used during a period when the influence of electromagnetic noise is desired to be avoided from the outside on the induced voltage and the reference voltage during the period when the HI side of the PWM drive phase is off and energization is not performed, or when the differential voltage between the reference voltage and the induced voltage cannot be used because ½ of the power supply voltage is used for the reference voltage and the reference voltage does not change. For the PWM energization off mask, Tde_mask_f for the first half and Tde_mask_r for the second half of one PWM cycle are provided respectively in the case of center-aligned PWM drive. The energization off period of the energized phase by this PWM energization off mask varies depending on the PWM drive duty.

The PWM mask (integrated) is illustrated by the shaded area in FIG. 10, and is a mask, associated with rectangular wave switching and integrating the PWM drive mask and the PWM energization off mask. This PWM mask (integrated), in the first half of one PWM cycle of the center-aligned PWM drive, starts from the start of the PWM cycle of the center-aligned PWM drive and extends to the elapse of the time Tpwm_on_mask after the ON of the HI side of the PWM drive phase. Then, in the second half, this PWM mask (integrated), starts from the OFF of the HI side of the PWM drive phase to the end of the PWM cycle, that is, the end of the PWM cycle Tperiod.

In the PWM mask (integrated), the PWM mask timer Toffset for starting counting in synchronization with the PWM cycle timer Tpwm, masks the first half of the PWM cycle from 0 to t101, and the PWM mask timer Twindow for starting counting from t101, masks the second half of the PWM cycle from t102 to the end of the PWM cycle Tperiod.

In the present embodiment, the zero-cross detection signal generation unit 121 receives, by the state control unit 12, the drive command signal So generated by a rectangular wave control unit 13, and executes processing at a predetermined timing. Without being limited to this, the state control unit 12 or the zero-cross detection signal generation unit 121, and the rectangular wave control unit 13 may independently execute processing by controlling respective timers based on the same triangular wave timing.

As illustrated in FIG. 9, in the mask processing (step S100) at the PWM mask (integrated), first, at the timing of the start of the triangular wave cycle, the rectangular wave control unit 13 starts counting by the PWM cycle timer Tpwm, and the zero-cross detection signal generation unit 121 starts counting by the PWM mask timer Toffset (step S110). After starting counting by the PWM cycle timer Tpwm, the rectangular wave control unit 13 determines whether the PWM cycle timer Tpwm has reached t1, as the LO side OFF time (step S120). At this time, the zero-cross detection signal generation unit 121 performs the mask processing so as not to generate the zero-cross detection signal Zo from the start of the PWM cycle.

When determining that the PWM cycle timer Tpwm has reached t1, as the LO side OFF time (step S120: YES), the rectangular wave control unit 13 generates the drive
command signal So for turning off an LO side FET of the PWM drive phase (step S130).

After generating the drive command signal So for turning off the LO side FET of the PWM drive phase, the rectangular wave control unit 13 further determines whether the PWM cycle timer Tpwm has reached t2, as the HI side ON time (step S140). Then, the rectangular wave control unit 13, when determining that the PWM cycle timer Tpwm has reached t2, as the HI side ON time (step S140: YES), generates the drive command signal So for turning on an HI side FET of the PWM drive phase (step S150).

After receiving the generated drive command signal So for turning on the HI side FET of the PWM drive phase, the zero-cross detection signal generation unit 121 further determines whether the PWM mask timer Toffset has reached the offset time t101 (step S160).

When the PWM mask timer Toffset is determined to have reached the offset time t101 (step S160: YES), the zero-cross detection signal generation unit 121 performs processing to enable the output of the zero-cross detection signal Zo, starts counting by the PWM mask timer Twindow from zero (step S170), and then determines whether the PWM mask timer Twindow has reached the window time t102 (step S180). During this period, the mask resolution is performed so that the zero-cross detection signal Zo can be output to the inductive kickback detection unit 122.

When the PWM mask timer Twindow is determined to have reached the window time t102 (step S180: YES), the zero-cross detection signal generation unit 121 performs processing to disable the output of the zero-cross detection signal Zo again (step S190). At this point, the mask processing is started again so that the zero-cross detection signal Zo is not output to the inductive kickback detection unit 122.

The rectangular wave control unit 13 determines whether t3, as the HI side OFF time of the PWM cycle timer Tpwm, has been reached (step S200), and when determined that t3, as the HI side OFF time of the PWM cycle timer Tpwm, has been reached (step S200: YES), generates the drive command signal So for turning off the HI side FET of the PWM drive phase (step S210).

The rectangular wave control unit 13 further determines whether the PWM cycle timer Tpwm has reached t4 as the LO side ON time, and when the PWM cycle timer Tpwm is determined to have reached t4 (step S220) as the LO side ON time (step S220: YES), generates the drive command signal So for turning on the LO side FET of the PWM drive phase (step S230).

The rectangular wave control unit 13 determines whether the PWM cycle timer Tpwm has reached the PWM cycle Tperiod (step S240), and returns to step S110 when the PWM cycle timer Tpwm has reached the PWM cycle Tperiod. In this example, the offset time t101 and the window time t102 of the PWM mask timer are configured to operate independently of the PWM cycle timer. However, the offset time t101 of the PWM mask timer may be synchronized with t2+Tpwm_on_mask of the PWM cycle timer, and the window time t102 of the PWM mask timer may be synchronized with t3 of the PWM cycle timer.

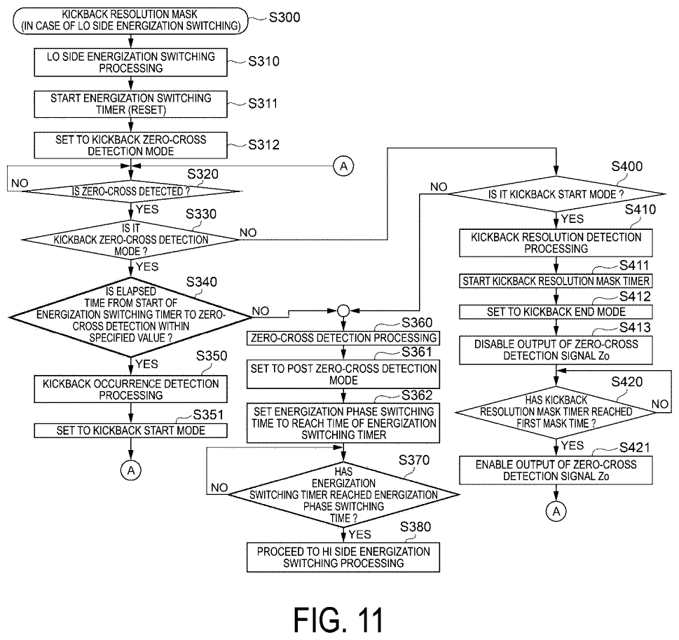

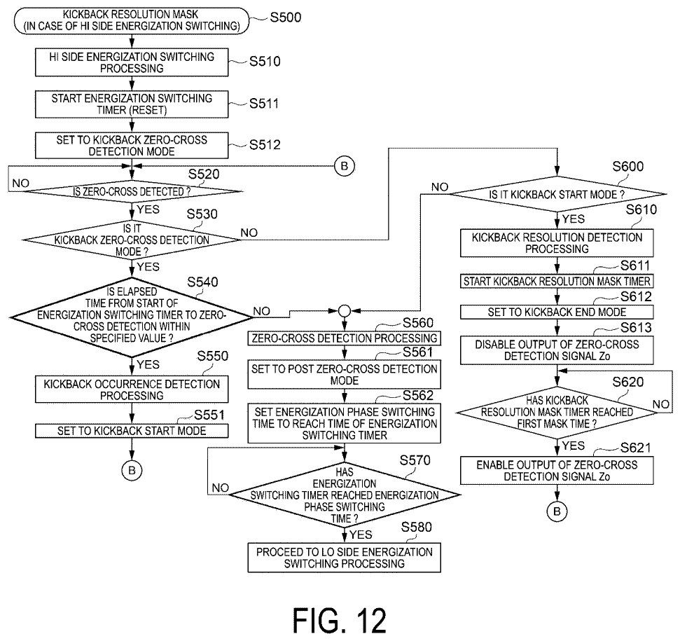

Next, a processing flow for executing the mask processing in the first mask time (kickback resolution mask) will be described with reference to FIGS. 11 and 12.

FIGS. 11 and 12 are flowcharts illustrating an example of a processing flow for executing the mask processing in the first mask time (kickback resolution mask). FIG. 11 is an example of LO side energization switching, and FIG. 12 is an example of HI side energization switching. The example of FIG. 11 corresponds to the timing charts of FIGS. 5 and 7, and the example of FIG. 12 corresponds to the timing charts of FIGS. 6 and 8.

As illustrated in FIG. 11, in the mask processing in LO side energization switching (step S300), first, the control circuit 1 executes LO side energization switching processing (step S310). Specifically, the rectangular wave control unit 13 changes the setting of the energized phase of the inverter circuit 2a (energization switching). Thereafter, the rectangular wave control unit 13 resets the energization switching timer Tsector during counting (step S311). Further, the inductive kickback detection unit 122 sets the state control unit 12 to the kickback zero-cross detection mode (step S312), and switches the variation detection direction of the differential voltage detection signal Vd in the zero-cross detection signal generation unit 121 from negative to positive.

The inductive kickback detection unit 122 determines whether the zero-cross is detected by monitoring the zero-cross detection signal Zo generated at the zero-cross detection signal generation unit 121 (step S320). The detection of a zero-cross can be determined when the signal of the differential voltage detection signal Vd varies from positive to negative or from negative to positive in the zero-cross detection signal generation unit 121. However, the variation detection direction of the differential voltage detection signal Vd in the zero-cross detection signal generation unit 121 is switched from negative to positive in step S310, so that the zero-cross detection signal Zo is generated when the signal of the differential voltage detection signal Vd varies from negative to positive, and the detection of a zero-cross can be determined (step S320: YES).

The inductive kickback detection unit 122, when determining that the zero-cross is detected (step S320: YES), determines whether the current setting of the state control unit 12 is the kickback zero-cross detection mode (step S330). In the case of the first detection of the zero-cross from the energization switching, the state control unit 12 is set to the kickback zero-cross detection mode in step S312, the current setting can be determined as the kickback zero-cross detection mode (step S330: YES).

The inductive kickback detection unit 122, when determining that the state control unit 12 is in the kickback zero-cross detection mode (step S330: YES), determines whether the detection of the zero-cross in step S320 determines whether the elapsed time of the energization switching timer Tsector reset by the LO side energization switching processing in step S310 is within a specified value (step S340). The specified value of the elapsed time is set to a sufficiently short time when inductive kickback may occur, for example, a period corresponding to 1 cycle of PWM driving. That is, when the inductive kickback detection unit 122 detects a zero-cross within a time corresponding to 1 cycle of PWM driving after switching between the energized phases to the coil, the inductive kickback detection unit 122 determines that inductive kickback has occurred and performs kickback occurrence detection processing (step S350). On the other hand, when the zero-cross is detected after the specified value, the inductive kickback detection unit 122 does not perform the kickback occurrence detection processing or the kickback resolution detection processing but performs the zero-cross detection processing of a step S360 described below, assuming that the zero-cross to be used for energization switching is detected.

When it is determined that the first zero-cross from the energization switching is detected within the specified value of the elapsed time from the energization switching (step S340: YES), the inductive kickback detection unit 122 determines that the inductive kickback has occurred and performs kickback occurrence detection processing (step S350), sets the state control unit 12 to the kickback start mode (step S351), and returns to the processing of step S320 again. The kickback occurrence detection processing is processing accompanying the detection of the inductive kickback occurrence. In the kickback occurrence detection processing, the inductive kickback detection unit 122 notifies the inductive kickback mask processing unit 123 of the occurrence of the inductive kickback, cancels the output of the zero-cross detection signal Zo generated by the inductive kickback occurrence to the rectangular wave control unit 13, and switches the variation detection direction of the differential voltage detection signal Vd from positive to negative at the zero-cross detection signal generation unit 121.

The inductive kickback detection unit 122, when determining that the second zero-cross from the energization switching is detected (step S320: YES), determines again whether the state control unit 12 is in the kickback zero-cross detection mode (step S330), but the result is NO because the state control unit 12 is set to the kickback start mode in the previous step S351. In this case, whether the state control unit 12 is in the kickback start mode (step S400) is further determined, but the state control unit 12 is set to the kickback start mode in the previous step S351, and thus the result is YES.

The inductive kickback detection unit 122, when determining that the state control unit 12 is in the kickback start mode (step S400: YES) in association with the detection of the second zero-cross from the energization switching, determines that the inductive kickback is resolved and executes the kickback resolution detection processing (step S410). The kickback resolution detection processing accompanies the detection of the inductive kickback resolution. In the kickback resolution detection processing, the inductive kickback detection unit 122 notifies the inductive kickback mask processing unit 123 of the resolution of the inductive kickback and cancels the output of the zero-cross detection signal Zo generated by the inductive kickback resolution to the rectangular wave control unit 13.

The inductive kickback mask processing unit 123, when receiving the notification of the inductive kickback resolution, starts the kickback resolution mask timer Tkb_end_mask (step S411). On the other hand, the inductive kickback detection unit 122 further changes the setting of the state control unit 12 from the kickback start mode to the kickback end mode (step S412), and switches the variation detection direction of the differential voltage detection signal Vd from negative to positive at the zero-cross detection signal generation unit 121.

When the state control unit 12 is set to the kickback end mode, the inductive kickback mask processing unit 123 invalidates the output of the zero-cross detection signal Zo (step S413), and determines whether the kickback resolution mask timer has reached the first mask time (step S420). The inductive kickback mask processing unit 123, when determining that the kickback resolution mask timer has reached the first mask time (step S420: YES), activates the output of the zero-cross detection signal Zo (step S421), thereby canceling the mask processing and returning to the processing of step S320 again.

The inductive kickback detection unit 122, when determining that the third zero-cross from the energization switching is detected (step S320: YES), determines again whether the state control unit 12 is in the kickback zero-cross detection mode (step S330), but the result is NO because the state control unit 12 is set to the kickback end mode in the previous step S412. In this case, whether the state control unit 12 is in the kickback start mode, is further determined (step S400), but the state control unit 12 is set to the kickback end mode in the previous step S412, and thus the result is NO.

The inductive kickback detection unit 122 performs zero-cross detection processing by regarding the detection of the third zero-cross from the energization switching, that is the zero-cross detection when the state control unit 12 is set to the kickback end mode, as the detection of the zero-cross to be used for the energization switching (step S360). The zero-cross detection processing (step S360) is also performed for the first zero-cross from the energization switching when the inductive kickback does not occur. After the zero-cross detection processing in step S360, the inductive kickback detection unit 122 sets the state control unit 12 to the post zero-cross detection mode (step S361), and notifies the inductive kickback mask processing unit 123 of the detection of the zero-cross to be used for the energization switching by regarding the zero-cross detection signal Zo as the zero-cross to be used for the energization switching.

When the inductive kickback mask processing unit 123 receives the notification of the detection of the zero-cross to be used for the energization switching by regarding the zero-cross detection signal Zo in step S360 as the zero-cross detection to be used for the energization switching, the zero-cross detection signal Zo generated by the zero-cross detection signal generation unit 121 is output to the rectangular wave control unit 13 because the first mask time has passed (step S420: YES) and the mask processing is resolved. The rectangular wave control unit 13 sets the energized phase switching time in the energization switching timer Tsector (step S362), and determines whether the energization switching timer Tsector reaches the energized phase switching time in the rectangular wave control unit 13 (step S370).

The control circuit 1, when determining that the energization switching timer Tsector of the rectangular wave control unit 13 has reached the energized phase switching time (step S370: YES), shifts to the HI side energization switching illustrated in FIG. 12 (step S380).

During the mask processing in the HI side energization switching (step S500) as illustrated in FIG. 12, first, the control circuit 1 executes the HI side energization switching processing (step S510). Specifically, the rectangular wave control unit 13 changes the setting of the energized phase of the inverter circuit 2a (energization switching). Then, the rectangular wave control unit 13 resets the energization switching timer Tsector under counting (step S511). Further, the inductive kickback detection unit 122 sets the state control unit 12 to the kickback zero-cross detection mode (step S512), and switches the variation detection direction of the differential voltage detection signal Vd at the zero-cross detection signal generation unit 121 from positive to negative.

The inductive kickback detection unit 122 monitors the zero-cross detection signal Zo generated at the zero-cross detection signal generation unit 121 to determine whether the zero-cross is detected (step S520). The detection of a zero-cross can be determined when the signal of the differential voltage detection signal Vd varies from positive to negative or from negative to positive in the zero-cross detection signal generation unit 121. However, the variation detection direction of the differential voltage detection signal Vd in the zero-cross detection signal generation unit 121 is switched from positive to negative in step S510, so that the zero-cross detection signal Zo is generated when the signal of the differential voltage detection signal Vd varies from positive to negative, and the detection of a zero-cross can be determined (step S520: YES).

The inductive kickback detection unit 122, when determining that the zero-cross is detected (step S520: YES), determines whether the current setting of the state control unit 12 is the kickback zero-cross detection mode (step S530). In the case of the first detection of the zero-cross from the energization switching, the state control unit 12 is set to the kickback zero-cross detection mode in step S512, the current setting can be determined as the kickback zero-cross detection mode (step S530: YES).

The inductive kickback detection unit 122, when determining that the state control unit 12 is in the kickback zero-cross detection mode (step S530: YES), determines whether the detection of the zero-cross in step S520 determines whether the elapsed time of the energization switching timer Tsector reset by the HI side energization switching processing in step S510 is within a specified value (step S540). The specified value of the elapsed time is set to a sufficiently short time when inductive kickback may occur, for example, a time corresponding to 1 cycle of PWM driving. That is, when the inductive kickback detection unit 122 detects a zero-cross within a time corresponding to 1 cycle of PWM driving after switching between the energized phases to the coil, the inductive kickback detection unit 122 determines that inductive kickback has occurred and performs kickback occurrence detection processing (step S550). On the other hand, when the zero-cross is detected after the specified value, the inductive kickback detection unit 122 does not perform the kickback occurrence detection processing or the kickback resolution detection processing but performs the zero-cross detection processing of a step S560 described below, assuming that the zero-cross to be used for energization switching is detected.

When it is determined that the first zero-cross from the energization switching is detected within the specified value of the elapsed time from the energization switching (step S540: YES), the inductive kickback detection unit 122 determines that the inductive kickback has occurred and performs kickback occurrence detection processing (step S550), sets the state control unit 12 to the kickback start mode (step S551), and returns to the processing of step S520 again. The kickback occurrence detection processing is processing accompanying the detection of the inductive kickback occurrence. In the kickback occurrence detection processing, the inductive kickback detection unit 122 notifies the inductive kickback mask processing unit 123 of the occurrence of the inductive kickback, cancels the output of the zero-cross detection signal Zo generated by the inductive kickback occurrence to the rectangular wave control unit 13, and switches the variation detection direction of the differential voltage detection signal Vd from negative to positive at the zero-cross detection signal generation unit 121.

The inductive kickback detection unit 122, when determining that the second zero-cross from the energization switching is detected (step S520: YES), determines again whether the state control unit 12 is in the kickback zero-cross detection mode (step S530), but the result is NO because the state control unit 12 is set to the kickback start mode in the previous step S551. In this case, whether the state control unit 12 is in the kickback start mode (step S600) is further determined, but the state control unit 12 is set to the kickback start mode in the previous step S551, and thus the result is YES.

The inductive kickback detection unit 122, when determining that the state control unit 12 is in the kickback start mode (step S600: YES) in association with the detection of the second zero-cross from the energization switching, determines that the inductive kickback is resolved and executes the kickback resolution detection processing (step S610). The kickback resolution detection processing accompanies the detection of the inductive kickback resolution. In the kickback resolution detection processing, the inductive kickback detection unit 122 notifies the inductive kickback mask processing unit 123 of the resolution of the inductive kickback and cancels the output of the zero-cross detection signal Zo generated by the inductive kickback resolution to the rectangular wave control unit 13.

The inductive kickback mask processing unit 123, when receiving the notification of the inductive kickback resolution, starts the kickback resolution mask timer Tkb_end_mask (step S611). On the other hand, the inductive kickback detection unit 122 further changes the setting of the state control unit 12 from the kickback start mode to the kickback end mode (step S612), and switches the variation detection direction of the differential voltage detection signal Vd from negative to positive at the zero-cross detection signal generation unit 121.

When the state control unit 12 is set to the kickback end mode, the inductive kickback mask processing unit 123 invalidates the output of the zero-cross detection signal Zo (step S613), and determines whether the kickback resolution mask timer has reached the first mask time (step S620). The inductive kickback mask processing unit 123, when determining that the kickback resolution mask timer has reached the first mask time (step S620: YES), activates the output of the zero-cross detection signal Zo (step S621), thereby canceling the mask processing and returning to the processing of step S520 again.

The inductive kickback detection unit 122, when determining that the third zero-cross from the energization switching is detected (step S520: YES), determines again whether the state control unit 12 is in the kickback zero-cross detection mode (step S530), but the result is NO because the state control unit 12 is set to the kickback end mode in the previous step S612. In this case, whether the state control unit 12 is in the kickback start mode, is further determined (step S600), but the state control unit 12 is set to the kickback end mode in the previous step S612, and thus the result is NO.

The inductive kickback detection unit 122 performs zero-cross detection processing by regarding the detection of the third zero-cross from the energization switching, that is, the zero-cross detection when the state control unit 12 is set to the kickback end mode, as the detection of the zero-cross to be used for the energization switching (step S560). The zero-cross detection processing (step S560) is also performed for the first zero-cross from the energization switching when the inductive kickback does not occur. After the zero-cross detection processing in step S560, the inductive kickback detection unit 122 sets the state control unit 12 to the post zero-cross detection mode (step S561), and notifies the inductive kickback mask processing unit 123 of the detection of the zero-cross to be used for the energization switching by regarding the zero-cross detection signal Zo as the zero-cross to be used for the energization switching.

When the inductive kickback mask processing unit 123 receives the notification of the detection of the zero-cross to be used for the energization switching by regarding the zero-cross detection signal Zo in step S560 as the zero-cross detection to be used for the energization switching, the zero-cross detection signal Zo generated by the zero-cross detection signal generation unit 121 is output to the rectangular wave control unit 13 because the first mask time has passed (step S620: YES) and the mask processing is resolved. The rectangular wave control unit 13 sets the energized phase switching time in the energization switching timer Tsector (step S562), and determines whether the energized switching timer Tsector reaches the energized phase switching time in the rectangular wave control unit 13 (step S570).

The control circuit 1, when determining that the energization switching timer Tsector of the rectangular wave control unit 13 has reached the energized phase switching time (step S570: YES), shifts to the LO side energization switching illustrated in FIG. 11 (step S580).

The control circuit 1 of the motor drive control device 10 according to the present embodiment:
detects, based on the phase voltage of each phase, a differential voltage detection signal as a differential voltage between an induced voltage generated at the coil of the non-energized phase and a reference voltage;
generates the drive command signal (So) for generating the drive control signal Sd in a PWM signal generation unit (14).

The drive control signal is a rectangular wave signal for:
switching between the energized phases to the corresponding coil based on zero-cross detection using the detected differential voltage detection signal, and
turning the switches of the inverter circuit 2a on and off to
switch between energized states of the coil of the energized phase. This control circuit 1
detects the occurrence and resolution of an inductive kickback generated in the coil of the non-energized phase after switching between the energized phases to the coil, and
masks
the zero-cross detection over a first predetermined time after detecting the resolution of the inductive kickback, and
masks the zero-cross detection over a second predetermined time at the rising and falling timings of the rectangular wave signal.

This enables the motor drive control device 10 to reliably avoid erroneous detection due to spiking or ringing, of a zero-cross used for energization switching, even when the motor is driven at high rotation, high output, and high load.

The control circuit 1 of the motor drive control device 10 according to the present embodiment, drives the motor by generating the drive control signal Sd for turning on and off the high-side switch and the low-side switch of the inverter circuit 2a energizing the coil, and masks the zero-cross detection over the second predetermined time at the on/off timing of the switches for the PWM drive phase of the energized phase among the high-side switches and the low-side switches of the inverter circuit 2a.

This enables the motor drive control device 10 to reliably avoid erroneous detection due to spiking or ringing, of a zero-cross used for energization switching, even when the motor is driven in control by turning on and off the inverter circuit 2a.

The control circuit 1 of the motor drive control device 10 according to the present embodiment, executes kickback resolution mask processing for masking the zero-cross detection over the first predetermined time after execution of the PWM drive mask processing for masking the zero-cross detection over the second predetermined time is completed.

This enables the motor drive control device 10 to avoid erroneous detection of a zero-cross used for energization switching, by the mask processing over both the first mask time and the second mask time.

The control circuit 1 of the motor drive control device 10 according to the present embodiment, in addition to masking for the first predetermined time and the second predetermined time, masks the zero-cross detection over the energization off period, as a period with the switches for the PWM drive phase of the energized phase turned off.

This allows the motor drive control device 10 to accurately detect the zero-cross used for energization switching even when the influence of electromagnetic noise is desired to be avoided from the outside on the induced voltage and the reference voltage during the non-energized period, or when ½ of the power supply voltage is used for the reference voltage.

In the control circuit 1 of the motor drive control device 10 according to the present embodiment, the inductive kickback detection unit 122 switches between the zero-cross detection modes based on the differential voltage detection signal according to the mode of the energization switching.

This allows the zero-cross used for energization switching to be accurately detected even when the inductive kickback does not occur or the duration of the inductive kickback is extremely short.

In the control circuit 1 of the motor drive control device 10 according to the present embodiment, the inductive kickback detection unit 122, when the first zero-cross is detected at a timing within a time of one cycle of PWM driving after switching between the energized phases to the coil, may process the detected zero-cross as the occurrence of the inductive kickback.

This can correctly detect the detected zero-cross as a zero-cross used for energization switching even when the inductive kickback does not occur.

### Expansion of Embodiments

The invention made by the present inventor has been specifically described above based on the embodiments, but the present invention is not limited to the embodiments, and it goes without saying that the present invention can be changed in various ways within the scope not departing from the gist of the present invention.

Further, in embodiments, a case with the speed command signal Sc including a target value (target rotation speed) of the rotation speed of the motor 3 is exemplified, but not limited to this case. For example, the speed command signal Sc may be a torque command signal for specifying the torque of the motor 3.

Further, in embodiments, the control circuit 1 is not limited to the circuit configuration described above. Various circuit configurations configured to meet the purpose of the present invention may be applied to the control circuit 1.

Specifically, for example, a plurality of comparators or A/D converters may be used instead of the multiplexer of the differential voltage detection circuit 15. The differential voltage detection circuit 15 may be configured as an analog circuit as illustrated in FIG. 3, or a digital circuit. The differential voltage detection circuit 15 may not shift by ½ of the power supply voltage.

Further, although the embodiment has been described as an example with reference to a mode with the drive signal of the HI side energized phase for driving the motor turning on of the high-side transistor (one of the High-side switches Q1, Q3, and Q5) and turning off of the low-side transistor (one of the Low-side switches Q2, Q4, and Q6) complementarily. However, the configuration may be adopted with the drive signal of the HI side energized phase turning on and off only the high-side transistor (one of the High-side switches Q1, Q3, and Q5).

Further, although the embodiment has been described with reference to a mode with the PWM drive centered, edge aligned PWM drive may be used.

Further, in the embodiment, a mode is described above as an example that by PWM drive using the power supply side of the inverter circuit as the PWM drive phase, and gate drive using the GND side as the GND phase, energization is performed by turning on the HI side switch of the PWM drive phase and turning on the LO side switch of the GND phase. Alternatively, by gate drive using the power supply side of the inverter circuit instead of the GND side, and PWM drive using the GND phase instead of the power supply side, energization may be performed by turning on the HI side switch of the power supply phase and turning on the LO side switch of the PWM drive phase, of the inverter circuit.

Further, in the embodiment, the driving of the motor is not limited to 120-degree energization rectangular wave drive. 150-degree energization rectangular wave drive or sine wave drive may be used.

Further, in the embodiment, a mode is described above as an example that PWM drive masks Tpwm_on_mask and Tpwm_off_mask are respectively provided as the second predetermined time, and the same value is used as the mask time when the switching element is turned on and when turned off.

Further, in the embodiment, the PWM energization off mask Tde_mask setting the energization off period of the energized phase as the mask time is used, but the PWM energization off mask may not be used by using the neutral point voltage instead of ½ of the power supply voltage as the reference voltage.

In embodiments, the number of phases of the motor 3 driven by the motor drive control device 10 is not limited to 3 phases.

The flowchart described above is a specific example, and is not limited to this flowchart. For example, other processing may be inserted between steps, or parallel processing may be performed.

### REFERENCE SIGNS LIST

1: Control circuit, 2: Drive circuit, 2a: Inverter circuit, 2b: Pre-drive circuit, 3: Motor, 10: Motor drive control device, 11: Drive command acquisition unit, 12: State control unit, 121: Zero-cross detection signal generation unit, 122: Inductive kickback detection unit, 123: Inductive kickback mask processing unit, 13: Rectangular wave control unit, 14: PWM signal generation unit, 15: Differential voltage detection circuit, 151: Plural resistance elements for limiting DC current and adjusting voltage, 152: Measurement phase selection multiplexer, 153: Differential amplifier circuit, 100: Motor unit, Q1 to Q6: Switching element, Sc: Speed command signal, Sd: Drive control signal, ωref: Target rotation speed, Zo: Zero-cross detection signal, So: Drive command signal, Sm: Measurement phase selection signal, Vd, Vd′: Differential voltage detection signal, Vm: Selected phase voltage signal, Vn: Neutral point voltage (Composite signal), Vdc, Vin: DC power supply, Vuh, Vul, Vvh, Vvl, Vwh, Vwl: Drive signal, Vu, Vv, Vw: Phase voltage signal, Lu, Lv, Lw: Coil

1. A motor drive control device comprising:
a control circuit configured to generate a drive control signal for driving a motor including a coil for at least one phase;
a drive circuit
including an inverter circuit including switches connected in series with each other, the switches being provided corresponding to a coil for each phase of the motor,
the drive circuit being configured to:
turn the switches on and off in response to the drive control signal to energize a coil for a corresponding phase; and switch between energized phases at a predetermined timing to rotate a rotor of the motor; and
a phase voltage detection circuit configured to detect a phase voltage generated between the inverter circuit and a coil for each phase of the motor,
wherein
the control circuit includes:
a differential voltage detection circuit configured to output, based on the detected phase voltage in each phase, a differential voltage between an induced voltage generated at a coil of a non-energized phase and a reference voltage as a differential voltage detection signal; and
a PWM signal generation circuit configured to generate the drive control signal, the drive control signal being a rectangular wave signal for
switching between the energized phases to the coil based on zero-cross detection using the differential voltage detection signal, and
turning the switches of the inverter circuit on and off to
switch between energized states of the coil of the energized phase, and
the control circuit is configured to,
when detecting an occurrence and a resolution of an inductive kickback generated at the coil of the non-energized phase after switching between the energized phases to the coil,
mask the zero-cross detection over a first predetermined time after detecting the resolution of the inductive kickback, and
mask the zero-cross detection over a second predetermined time at rising and falling timings of the rectangular wave signal.

2. The motor drive control device according to claim 1, wherein
the switches of the inverter circuit include high-side switches and low-side switches,
the PWM signal generation circuit drives the motor by generating the drive control signal for turning on and off the high-side switches and the low-side switches of the inverter circuit to energize the coil, and
the control circuit masks the zero-cross detection over the second predetermined time at an on/off timing of the switches for a PWM drive phase of the energized phase among the high-side switches and the low-side switches of the inverter circuit.

3. The motor drive control device according to claim 1, wherein
the control circuit executes kickback resolution mask processing for masking the zero-cross detection over the first predetermined time after execution of PWM drive mask processing for masking the zero-cross detection over the second predetermined time is completed.

4. The motor drive control device according to claim 2, wherein
the switches of the inverter circuit include high-side switches and low-side switches,
the PWM signal generation circuit drives the motor by generating the drive control signal for turning on and off the switches of the inverter circuit to energize the coil, and
the control circuit masks the zero-cross detection over an energization off period, the energization off period being a period with the switches for the PWM drive phase of the energized phase turned off.

5. The motor drive control device according to claim 1, wherein
the control circuit further detects an occurrence and a resolution of an inductive kickback generated at the coil of the non-energized phase after switching between the energized phases to the coil, and
the control circuit switches between zero-cross detection modes based on the differential voltage detection signal according to an energization switching mode by,
when an energized phase at a power supply side is switched to another energized phase by HI side energization switching,
setting a variation detection direction of a differential voltage detection signal
at a time of an inductive kickback occurrence to a direction from positive to negative, and
setting a variation detection direction of a differential voltage detection signal at a time of an inductive kickback resolution to a direction from negative to positive; and
when an energized phase at a GND side is switched to another energized phase by LO side energization switching, setting a variation detection direction of the differential voltage detection signal at a time of an inductive kickback occurrence to a direction from negative to positive, and
setting a variation detection direction of a differential voltage detection signal at a time of an inductive kickback resolution to a direction from positive to negative.

6. The motor drive control device according to claim 1, wherein
the control circuit detects the occurrence of the inductive kickback when a first zero-cross is detected within a time of one cycle of PWM driving after switching between the energized phases to the coil.

7. A motor drive control method to be executed in a motor drive control device including:
a control circuit configured to generate a drive control signal for driving a motor including a coil for at least one phase;
a drive circuit including an inverter circuit including switches connected in series with each other,
the switches being provided corresponding to a coil for each phase of the motor, the drive circuit being
configured to:
turn the switches on and off in response to the drive control signal to energize a coil for a corresponding phase; and
switch between energized phases at a predetermined timing to rotate a rotor of the motor; and
a phase voltage detection circuit configured to detect a phase voltage generated between the inverter circuit and a coil for each phase of the motor,
the motor drive control method comprising:
a first step of outputting, based on the detected phase voltage in each phase, a differential voltage between an induced voltage generated at a coil of a non-energized phase and a reference voltage as a differential voltage detection signal;
a second step of performing zero-cross detection based on the differential voltage detection signal;
a third step of generating the drive control signal,
the drive control signal being a rectangular wave signal for
switching between the energized phases to the coil based on the zero-cross detection, and
turning the switches of the inverter circuit on and off to
switch between energized states of the coil of the energized phase;
a fourth step of detecting an occurrence and a resolution of an inductive kickback generated at the coil of the non-energized phase after switching between the energized phases to the coil; and
a fifth step of masking
the zero-cross detection over a first predetermined time after detecting the resolution of the inductive kickback, and
masking the zero-cross detection over a second predetermined time upon rising and falling of the rectangular wave signal.
